(19) United States
(12) Patent Application Publication
(10) Pub. No.: US 2023/0320150 A1
(43) Pub. Date: Oct. 5, 2023

(54) DISPLAY DEVICE

(71) Applicant: Samsung Display Co., Ltd., Yongin-si (KR)

(72) Inventors: Sung Eun LEE, Seoul (KR); Youn Joon KIM, Seoul (KR); Jong Hyun CHOI, Seoul (KR); Hee Suk NAMGUNG, Hwaseong-si (KR); Min Jeong OH, Gimpo-si (KR); Ki June LEE, Yongin-si (KR); Jin Ho JU, Seoul (KR)

(21) Appl. No.: 18/099,676

(22) Filed: Jan. 20, 2023

(30) Foreign Application Priority Data
Apr. 4, 2022 (KR) 10-2022-0041718

(51) Int. Cl. H10K 59/131; H10K 59/121; H10K 77/10

(52) U.S. Cl. CPC H10K 59/131; H10K 59/1216; H10K 59/1213; H10K 77/111; H10K 2102/311

(57) ABSTRACT

A display device includes a substrate including a first non-bendable portion, a second non-bendable portion, and a bendable portion that is interposed between the first and the second non-bendable portions, a metal plate disposed on a rear face of the substrate and including a first plate portion overlapping the first non-bendable portion, a second plate portion overlapping the second non-bendable portion, and a connection portion between the first plate portion and the second plate portion, the connection portion including a first bar and a second bar that are separated by a slit; the substrate includes a first area in which the first bar and the bendable portion overlap each other, a second area in which the slit and the bendable portion overlap each other, and a third area in which the second bar and the bendable portion overlap each other. The second area is between the first and second areas.

### CROSS-REFERENCE TO RELATED APPLICATION

This application claims priority from Korean Patent Application No. 10-2022-0041718 filed on Apr. 4, 2022 in the Korean Intellectual Property Office, and all the benefits accruing therefrom under 35 U.S.C. 119, the contents of which in its entirety are herein incorporated by reference.

### BACKGROUND

### Field

The disclosure relates to a display device.

### Description of Related Art

A display device displays an image, and includes a display panel such as an organic light-emitting display panel including an organic light emitting diode (OLED) or a quantum dot electroluminescent element (QD-EL) or a liquid crystal display panel.

In one example, a mobile electronic device includes a display device to provide an image to a user. A percentage of the portable electronic device having a larger display screen while having the same or smaller volume or thickness than that in the prior art is increasing. A foldable display device or a bendable display having that allows the device to be folded for compactness and unfolded for a larger screen is being developed.

In the foldable display device, a metal plate having at least a portion that can be expanded and contracted when a display panel is folded may be disposed on a rear face of the display panel.

### SUMMARY

The disclosure pertains to a high-resolution display device in which a partial line disposed on a slit area of a metal plate overlapping a bendable portion of the display device is removed such that the device is robust and flexible against external shock.

Benefits and advantages according to the disclosure may be understood based on following descriptions, and may be more clearly understood based on embodiments according to the disclosure. Further, it will be easily understood that the benefits and advantages according to the disclosure may be realized using means shown in the claims and combinations thereof.

A display device comprises a substrate including a first non-bendable portion, a second non-bendable portion, and a bendable portion therebetween. A metal plate is disposed on a rear face of the substrate, wherein the metal plate includes a first plate portion overlapping the first non-bendable portion, a second plate portion overlapping the second non-bendable portion, and a connection portion between the first plate portion and the second plate portion, the connection portion including a first bar and a second bar that are separated by a slit. The substrate includes a first area in which the first bar and the bendable portion overlap, a second area in which the slit and the bendable portion overlap, and a third area in which the second bar and the bendable portion overlap, wherein the second area is interposed between the first and third areas. An initialization line includes a first portion disposed on the first area, and a second portion disposed on the third area and spaced apart from the first portion with the second area being disposed between the first and second portions. A first pixel circuit is disposed on the first area and connected to the first portion of the initialization line, a second pixel circuit disposed on the third area and connected to the second portion of the initialization line, and a first connection line connects the first portion and the second portion to each other, wherein the first connection line is disposed on the first area, the second area, and the third area, and wherein the first connection line is disposed in a different layer from a layer in which the first portion and the second portion are disposed.

A display may further comprise a buffer layer disposed on the substrate, a first gate insulating layer disposed on the buffer layer, a second gate insulating layer disposed on the first gate insulating layer, an inter insulating layer disposed on the second gate insulating layer, and an opening defined in the second area so as to expose the first connection line.

A display may further comprise a lower metal layer disposed between the substrate and the buffer layer, wherein the first connection line may be disposed in the same layer as a layer in which the lower metal layer is disposed, and wherein the first connection line may be made of the same material as a material of the lower metal layer.

The first pixel circuit may include a semiconductor layer disposed between the buffer layer and the first gate insulating layer, a gate electrode disposed between the first gate insulating layer and the second gate insulating layer, and a capacitor electrode disposed between the second gate insulating layer and the inter insulating layer, wherein the first portion may be disposed between a portion of the buffer layer and a portion of the first gate insulating layer disposed in the first area, wherein the second portion may be disposed between a portion of the buffer layer and a portion of the first gate insulating layer disposed in the third area, and wherein the first portion and the second portion may be made of the same material as a material of the semiconductor layer.

The lower metal layer may overlap the semiconductor layer.

A display may further comprise a second connection line connecting the first portion and the second portion to each other, and wherein the second connection line may be disposed in the first area, the second area, and the third area, and wherein the second connection line may be disposed in a different layer from a layer of the first connection line.

The second connection line may overlap the first connection line.

A display may further comprise a via insulating layer disposed in the first area, the second area, and the third area, and wherein a via insulating layer may be disposed on the inter insulating layer, wherein the via insulating layer may fill the opening in the second area, and wherein the via insulating layer may directly contact a portion of the first connection line through the opening.

A thickness of a portion of the via insulating layer disposed in the second area may be larger than a thickness of a portion of the via insulating layer disposed in each of the first area and the third area.

A display may further comprise the buffer layer covering a portion of the first connection line in the second area, wherein the second connection line may be in direct contact with the buffer layer.

The second connection line may be made of the same material as a material of the gate electrode.

The second connection line may be made of the same material as a material of the capacitor electrode.

A display may further comprise a first pixel circuit disposed on the third area, a first light-emitting element disposed on the first area and connected to the first pixel circuit disposed on the first area, a first light-emitting element disposed on the third area and connected to the first pixel circuit disposed on the third area, and a second light-emitting element disposed on the second area and connected to the second pixel circuit disposed on the third area, wherein the first light-emitting element may not overlap the first connection line, and wherein the second light-emitting element may overlap the first connection line.

Neither of the first pixel circuit and the second pixel circuit may overlap the second area.

In another aspect, a display device comprises a substrate including a first and a second non-bendable portions, and a bendable portion that is disposed between the first non-bendable portion and the second non-bendable portion, and a metal plate disposed on a rear face of the substrate. The metal plate includes a first plate portion overlapping the first non-bendable portion, a second plate portion overlapping the second non-bendable portion, and a connection portion between the first plate portion and the second plate portion, the connection portion including a first bar and a second bar that are separated by a slit. the substrate includes a first area in which the first bar and the bendable portion overlap, a second area in which the slit and the bendable portion overlap, and a third area in which the other of the bars and the bendable portion overlap, wherein the second area is interposed between the first and third areas. A first light-emitting element is disposed on each of the first area and the third area, a second light-emitting element disposed on the second area, a first pixel circuit is disposed on each of the first area and the third area, and a second pixel circuit is disposed on the third area, wherein the first light-emitting element overlaps and is connected to the first pixel circuit in each of the first and third areas, and wherein the second light-emitting element is in a mutually exclusive area with the first pixel circuit and the second pixel circuit and is connected to the second pixel circuit.

The display device may further comprise a voltage line having a first portion disposed on the first area, and a second portion disposed on the third area and spaced apart from the first portion while the second area is disposed therebetween, and a connection line connecting the first portion and the second portion to each other, wherein the first portion may be connected to the first pixel circuit on the first area, wherein the second portion may be connected to the second pixel circuit on the third area, wherein the connection line may be disposed on the first area, the second area, and the third area, and wherein the connection line may be disposed in a different layer from a layer of each of the first portion and the second portion.

The display device may further include a connection electrode disposed on the first area and the second area, and connected to the second pixel circuit on the third area, wherein the second light-emitting element may be connected to a portion of the connection electrode on the second area.

At least a portion of the connection line may overlap the connection electrode.

The connection line and the first light-emitting element are on mutually exclusive parts of each of the first and third areas, and wherein the connection line may overlap the second light-emitting element.

Neither of the first pixel circuit and the second pixel circuit may non-overlap the second area.

The partial line disposed on the slit area of the metal plate overlapping the bendable portion may be removed such that the bendable portion of the display device may have the same level of impact resistance as that of the non-bendable portion of the display device.

Effects of the disclosure are not limited to the above-mentioned effects, and other effects as not mentioned will be clearly understood by those skilled in the art from following descriptions.

### BRIEF DESCRIPTION OF DRAWINGS

The above and other aspects and features of the disclosure will become more apparent by describing in detail illustrative embodiments thereof with reference to the attached drawings, in which:

FIG. 1 is a perspective view of a display device according to one embodiment;

FIG. 2 is a perspective view showing a folded state of a display device according to one embodiment;

FIG. 3 is an exploded perspective view of the display device of FIG. 1;

FIG. 4 is a cross-sectional view of the display device cut along a line I-I′ in FIG. 1;

FIG. 5 is a plan view of a metal plate according to one embodiment;

FIG. 6 is a plan view showing a display panel of the display device according to an embodiment of FIG. 1;

FIG. 7 is a circuit diagram to illustrate a circuit structure of a pixel;

FIG. 8 is a diagram schematically showing an arrangement of a light-emitting element and a pixel circuit disposed in an A area of FIG. 1;

FIG. 9 is a diagram schematically showing an arrangement of a pixel circuit and lines disposed in the A area of FIG. 1;

FIG. 10 is an enlarged view of a B area of FIG. 9;

FIG. 11 is a cross-sectional view schematically showing a cross-section taken along a line II-II′ of FIG. 8 according to one embodiment;

FIG. 12 is a cross-sectional view schematically showing a cross-section taken along a line III-III′ of FIG. 10 according to one embodiment;

FIG. 13 is an enlarged view of a C area of FIG. 12 according to one embodiment;

FIG. 14 is an enlarged view of the area C of FIG. 12 according to another embodiment; and

FIG. 15 to FIG. 21 are enlarged views of the area C of FIG. 12 according to still further embodiment.

### DETAILED DESCRIPTIONS

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the disclosure, numerous specific details are set forth in order to provide a thorough understanding of the disclosure. However, it will be understood that the disclosure may be practiced without these specific details. In other instances, well-known methods, procedures, components, and circuits have not been described in detail so as not to unnecessarily obscure aspects of the disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the disclosure as defined by the appended claims.

A shape, a size, a percentage, an angle, a number, etc. disclosed in the drawings for describing embodiments of the disclosure are illustrative, and the disclosure is not limited thereto. The same reference numerals refer to the same elements herein. Further, descriptions and details of well-known steps and elements are omitted for simplicity of the description. Furthermore, in the following detailed description of the disclosure, numerous specific details are set forth in order to provide a thorough understanding of the disclosure. However, it will be understood that the disclosure may be practiced without these specific details. In other instances, well-known methods, procedures, components, and circuits have not been described in detail so as not to unnecessarily obscure aspects of the disclosure.

The terminology used herein is for the purpose of describing particular embodiments only and is not intended to limit the disclosure. As used herein, the singular constitutes “a” and “an” are intended to include the plural constitutes as well, unless the context clearly indicates otherwise. It will be further understood that the terms “comprises,” “comprising,” “includes,” and “including,” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the disclosure.

In addition, it will also be understood that when a first element or layer is referred to as being “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be. In addition, it will also be understood that when an element or layer is referred to as being “between” two elements or layers, it may be the only element or layer between the two elements or layers, or one or more intervening elements or layers may also be.

Further, as used herein, when a layer, film, region, plate, or the like is disposed “on” or “on top” of another layer, film, region, plate, or the like, the former may directly contact the latter or still another layer, film, region, plate, or the like may be disposed between the former and the latter. As used herein, when a layer, film, region, plate, or the like is directly disposed “on” or “on top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after,” “subsequent to”, “before”, etc., another event may occur therebetween unless “directly after”, “directly subsequent” or “directly before” is not indicated.

The features of the various embodiments of the disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings is turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

Hereinafter, specific embodiments will be described with reference to the accompanying drawings.

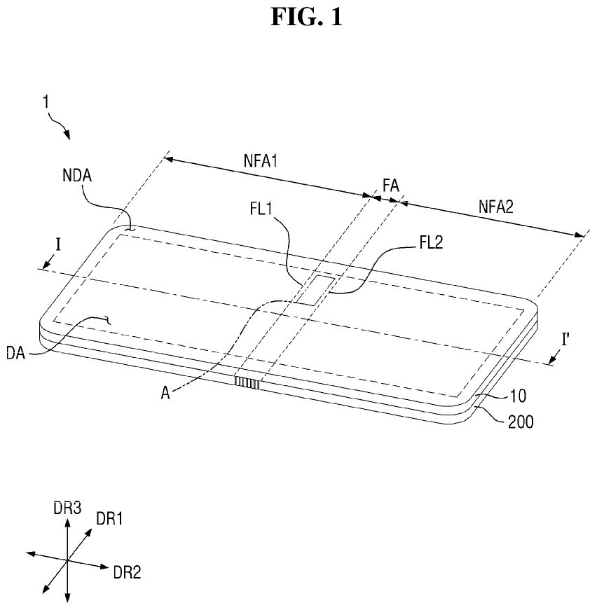

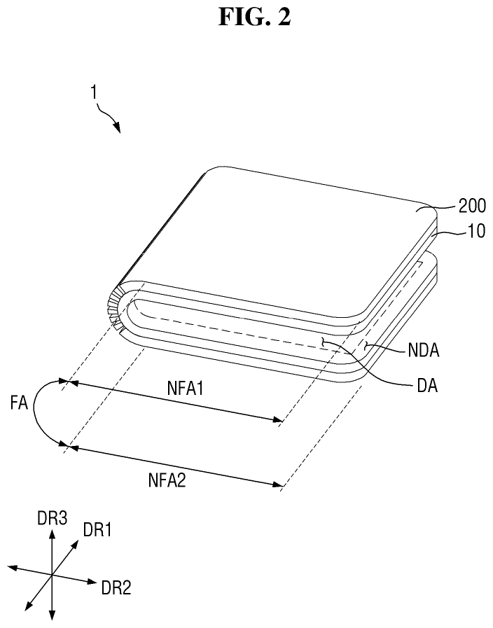

FIG. 1 is a perspective view of a display device according to one embodiment. FIG. 2 is a perspective view showing a folded state of the display device according to one embodiment.

An example in which a display device 1 according to one embodiment is applied to a smartphone will be described. However, the disclosure is not limited thereto. For example, the display device 1 according to embodiments of the disclosure may be applied to a mobile phone, a tablet PC, a PDA (Personal Digital Assistant), a PMP (Portable Multimedia Player), a television, a game device, a wrist watch type electronic device, a head mounted display, a personal computer monitor, a notebook computer, a car navigation system, a car dashboard, a digital camera, a camcorder, an outdoor billboard, an electric sign, a medical device, an inspection device, various home appliances such as a refrigerator and a washing machine, or Internet of Things devices. Hereinafter, specific embodiments will be described with reference to the accompanying drawings.

Hereinafter, a first direction DR1, a second direction DR2, and a third direction DR3 may extend in different directions and intersect each other. The first direction DR1 may be a length direction, the second direction DR2 may be a width direction, in the third direction DR3 may be a thickness direction. The third direction DR3 may include a front direction facing upward in the drawing, and a rear direction facing downward in the drawing. Accordingly, one face of a member facing in the front direction may be referred to as a “front face,” while the other face of the member that faces in the rear direction may be referred to as a “rear face.” However, the directions may refer to relative directions. The directions may not be limited to the example.

Referring to FIG. 1 and FIG. 2, the display device 1 according to one embodiment may have a rectangular or square shape in a plan view. In one embodiment, the display device 1 may have a rectangular shape in which corners are right angles, or a rectangular shape with rounded corners. The display device 1 may include two short-sides extending in the first direction DR1 and two long-sides extending in the second direction DR2 in a plan view. However, the disclosure is not limited thereto, and the display device 1 may have various shapes. For example, the display device 1 may have a rectangular shape in which two long-sides extending in the first direction DR1 and two short-sides extending in the second direction DR2 in a planar shape.

The display device 1 may include a front face and a rear face. The display device 1 may further include at least one side face between the front face and the rear face.

The display device 1 includes at least one display face that provides visual information and often receives user input. In one embodiment, the display face may be the front face of the display device 1. The display face may extend along and across the bendable portion FA and non-bendable portions NFA1 and NFA2 to be described later. In some embodiments, both the front face and the rear face of the display device 1 may be a display face. In some embodiments, a plurality of the display faces may be two or more of the front face, the rear face, and the side face of the display device 1.

The display face may include a display area DA and a non-display area NDA.

The display area DA displays an image or video. A shape of the display area DA in a plan view may correspond to a shape of the display device 1. For example, when the display device 1 has a rectangular shape in a plan view, the display area DA may also have a rectangular shape.

The display area DA may be an area including a plurality of pixels for displaying an image. The plurality of pixels may be arranged in a matrix manner. The shape of each of the plurality of pixels may be rectangular, rhombus, or square in a plan view. However, the disclosure is not limited thereto. For example, the shape of each of the plurality of pixels may be a polygon other than a rectangle, a rhombus, or a square, or a circle, or an oval in a plan view. Not all the pixels are limited to having the same shape.

The non-display area NDA may be an area that does not display an image because the area NDA does not include the pixel. The non-display area NDA may be disposed around the display area DA. The non-display area NDA may be disposed to surround the display area DA as shown in FIG. 1. However, the disclosure is not limited thereto. In some embodiments, the display area DA may be partially surrounded with the non-display area NDA. In some embodiments, the display area DA may have a rectangular shape, and the non-display area NDA may be disposed around four sides of the display area DA. However, the disclosure is not limited thereto.

In one embodiment, the display device 1 may be a foldable device. The display device 1 may be folded or unfolded. As used herein, “folding” may include “bending.” Specifically, the display device 1 may have a portion overlapping with another portion, a portion thereof may be bent to be inclined with respect to another portion, or an entirety of the display device 1 may be flattened. In one embodiment, the display device 1 may be unfolded such that a portion thereof is folded with respect to another portion at an angle of more than about 0 degrees and smaller than 180 degrees defined therebetween or may be unfolded with respect to another portion at about 180 degrees defined therebetween.

The display device 1 may be folded inward and/or folded outward. The state of being folded inward indicates that a portion of the display face of the display device 1 faces another portion of the display face. The state of being folded outward indicates that two portions of the display face do not face each other. For example, in an example state of a device being folded outward, a portion of a rear face of the display device 1 faces another portion of the rear face. In an embodiment, the display device 1 may be folded inward. However, the disclosure is not limited to any one folded state.

The display device 1 may have a folded state or an unfolded state. The folded state includes a state in which the display device 1 is bent. Specifically, the folded state may be a state in which a portion of the display device 1 is bent to form an angle with respect to another portion. The unfolded state may be a state in which a portion of the display device 1 is coplanar with another portion. Alternatively, the folded state is a state in which an angle between a portion of the display device 1 and another portion thereof is greater than or equal to about 0 degrees and smaller than 180 degrees and/or is greater than about 180 degrees and smaller than 360 degrees. The unfolded state is a state between an angle between a portion of the display device 1 and another portion thereof is about 180 degrees. In this regard, the portion and another portion defining the angle with each other may be the non-bendable portions NFA1 and NFA2, which will be described later, respectively.

The display device 1 may be divided into the bendable portion FA and the non-bendable portions NFA1 and NFA2. The bendable portion FA may refer to a portion which may be bent as the display device 1 is folded. Each of the non-bendable portions NFA1 and NFA2 may refer to a portion that is not bent as the display device 1 is folded. The non-bendable portions NFA1 and NFA2 may include a first non-bendable portion NFA1 and a second non-bendable portion NFA2. In one embodiment, the first non-bendable portion NFA1 and the second non-bendable portion NFA2 may be arranged in the second direction DR2. The bendable portion FA may be disposed between the first non-bendable portion NFA1 and the second non-bendable portion NFA2.

In this embodiment, one bendable portion FA and two non-bendable portions NFA1 and NFA2 are defined in the display device 1. However, the disclosure is not limited thereto. In some embodiments, a plurality of bendable portions FA and a plurality of non-bendable portions NFA1 and NFA2 may be defined in the display device 1.

The display device 1 may be folded or unfolded based on a first folding line FL1 and a second folding line FL2. In one embodiment, the display device 1 may be folded or unfolded based on the first folding line FL1 and the second folding line FL2 extending in the first direction DR1. However, the disclosure is not limited thereto.

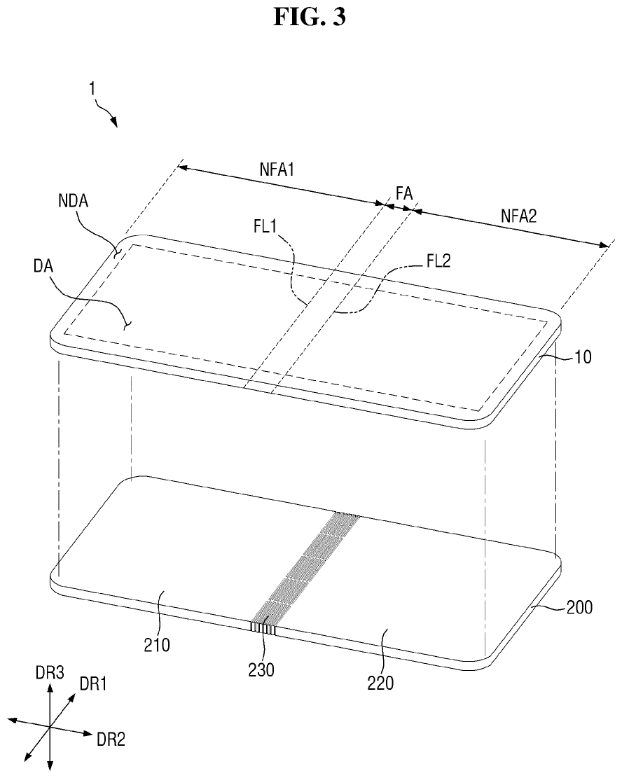

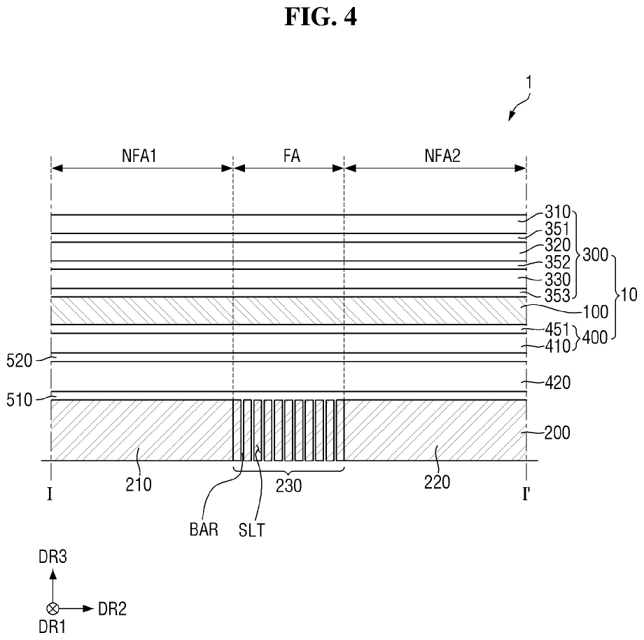

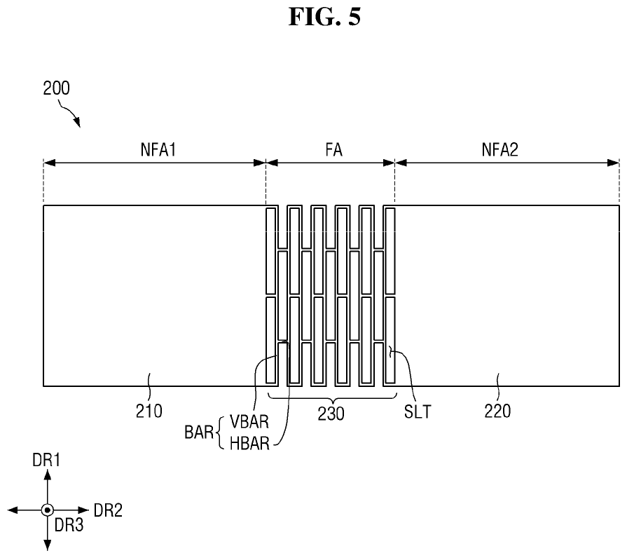

FIG. 3 is an exploded perspective view of the display device of FIG. 1. FIG. 4 is a cross-sectional view of the display device cut along a line I-I′ in FIG. 1. FIG. 5 is a plan view of a metal plate according to one embodiment.

Referring to FIG. 3, a front face of a display module 10 may constitute the front face of the display device 1, and a metal plate 200 may be disposed on the rear face of the display module 10. That is, the metal plate 200 may be disposed to overlap the first non-bendable portion NFA1, the bendable portion FA, and the second non-bendable portion NFA2. The metal plate 200 may be flexible and may be folded based on the first folding line FL1 and the second folding line FL2.

The metal plate 200 may have a rectangular shape elongated in the second direction DR2. However, the disclosure is not limited thereto. In one embodiment, the metal plate 200 includes a front face and a rear face parallel to a plane defined by the first direction DR1 and the second direction DR2, and side faces extending in the third direction DR3 and disposed between the front face and the rear face.

In some embodiments, the metal plate 200 may have a size larger than that of the display module 10, and a length in each in the first direction DR1 and the second direction DR2 of the metal plate 200 may be larger than that of the display module 10. For example, the metal plate 200 may have a small thickness of about 0.1 mm to 0.2 mm.

A detailed description of a pattern included in a connection portion 230 of the metal plate 200 will be described later in conjunction with FIG. 5.

The display module 10 has flexibility. The display module 10 may extend along and across the first non-bendable portion NFA1, the bendable portion FA, and the second non-bendable portion NFA2, and may be folded based on the first folding line FL1 and the second folding line FL2.

Referring to FIG. 4, the display module 10 may include a display panel 100, a front stack structure 300 and a rear stack structure 400.

The display module 10 may include the display panel 100, the front stack structure 300 stacked on a front face of the display panel 100, and the rear stack structure 400 stacked on a rear face of the display panel 100. The front face of the display panel 100 may be a face toward in a direction in which the display panel 100 displays a screen, and the rear face of the display panel 100 may be a face to opposite to the front face.

The display panel 100 displays a screen or an image, and examples thereof may include not only a self-light-emitting display panel such as an organic light-emitting display panel (OLED), an inorganic light-emitting display panel (inorganic EL), a quantum dot light-emitting display panel (QED), a micro LED display panel (micro-LED), and a nano-LED display panel (nano-LED), a plasma display panel (PDP), a field emission display panel (FED), and a cathode ray display panel (CRT), and a non-self-light-receiving display panel such as a liquid crystal display panel (LCD), an electrophoretic display panel (EPD), etc. Hereinafter, a example in which the display panel 100 is embodied as the organic light-emitting display panel will be described. Unless a special distinction is required, the organic light-emitting display panel applied to an embodiment will be simply abbreviated as a display panel. However, an embodiment is not limited to the organic light-emitting display panel. Other types of display panels as listed above or known in the art may be applied within a technical spirit or scope of the disclosure.

The display panel 100 may further include a touch member (not shown). The touch member (not shown) may be provided as a separate panel or film from the display panel 100 and may be attached to the display panel 100. However, the touch member may be disposed inside the display panel 100 and may be provided in a form of a touch layer. In a following embodiment, a case in which the touch member is provided inside the display panel 100 and is included in the display panel 100 is exemplified. However, the disclosure is not limited thereto.

The front stack structure 300 is disposed on the front face of the display panel 100. The front stack structure 300 may include a polarization member 330, a cover window 320, and a cover window protective layer 310 sequentially frontwards stacked on the display panel 100.

The polarization member 330 polarizes light which passes therethrough. The polarization member 330 may serve to reduce external light reflection. In one embodiment, the polarization member 330 may be embodied as a polarization film. The polarization film may include a polarization layer and a protective base disposed on each of a top and a bottom of the polarization layer so as to protect the polarization layer. The polarization layer may include a polyvinyl alcohol film. The polarization layer may be stretched in one direction. The direction in which the polarization layer is stretched may be an absorption axis, while a direction perpendicular thereto may be a transmission axis. The protective base may be disposed on each face of the polarization layer. The protective base may be made of cellulose resin such as triacetyl cellulose, polyester resin, or the like. However, the disclosure is not limited thereto.

The cover window 320 may be disposed on a front face of the polarization member 330. The cover window 320 protects the display panel 100. The cover window 320 may be made of a transparent material. The cover window 320 may be made of, for example, glass or plastic.

When the cover window 320 includes glass, the glass may be embodied as an ultra-thin glass (UTG) or a thin-film glass. When the glass is embodied as the UTG or the thin-film glass, the glass may have flexible properties and thus may be bent, folded, or rolled. A thickness of the glass may be, for example, in a range of 10 μm to 300 μm. Specifically, the glass having a thickness of 30 μm to 80 μm or about 50 μm may be applied. The glass of the cover window 320 may include soda lime glass, alkali aluminosilicate glass, borosilicate glass, or lithium alumina silicate glass. The glass of the cover window 320 may include chemically strengthened or thermally strengthened glass to achieve high strength. Chemical strengthening may be achieved via an ion exchange treatment process in an alkali salt. The ion exchange treatment process may be performed two or more times.

When the cover window 320 includes plastic, the cover window 320 more advantageously exhibits flexible properties such as foldability. Examples of the plastic applicable to the cover window 320 may include, but may not be limited to, polyimide, polyacrylate, polymethylmethacrylate (PMMA), polycarbonate (PC), polyethylenenaphthalate (PEN), polyvinylidene chloride, polyvinylidene difluoride (PVDF), polystyrene, ethylene vinylalcohol copolymer, polyethersulphone (PES), polyetherimide (PEI), polyphenylene sulfide (PPS), polyallylate, tri-acetyl cellulose (TAC), cellulose acetate propionate (CAP), and the like. The plastic cover window 320 may include one or more of the plastic materials enumerated above.

The cover window protective layer 310 may be disposed on a front face of the cover window 320. The cover window protective layer 310 may perform at least one of scattering prevention, shock absorption, engraving prevention, fingerprint prevention, and glare prevention of the cover window 320. The cover window protective layer 310 may include a transparent polymer film. The transparent polymer film may include at least one of PET (PolyEthylene Terephthalate), PEN (PolyEthylene Naphthalate), PES (Polyether Sulfone), PI (Polylmide), PAR (PolyARylate), PC (PolyCarbonate), PMMA (PolyMethyl MethAcrylate) or COC (CycloOlefin Copolymer) resin.

The front stack structure 300 may include front bonding members 351, 352, and 353, each bonding stacked members adjacent thereto to each other. For example, the first front bonding member 351 may be disposed between the cover window 320 and the cover window protective layer 310 to bond the cover window 320 and the cover window protective layer 310 to each other. The second front bonding member 352 may be disposed between the cover window 320 and the polarization member 330 to bond the cover window 320 and the polarization member 330 to each other. The third front bonding member 353 may be disposed between the polarization member 330 and the display panel 100 to bond the polarization member 330 and the display panel 100 to each other. That is, the front bonding members 351, 352, and 353 may attach the layers onto one face of the display panel 100. In this regard, the first front bonding member 351 may act as a protective layer bonding member for attaching the cover window protective layer 310 thereto. The second front bonding member 352 may act as a window bonding member that attaches the cover window 320 thereto. The third front bonding member 353 may act as a polarizing member bonding member for attaching the polarization member 330 thereto. Each of the front bonding members 351, 352, and 353 may be optically transparent.

The rear stack structure 400 is disposed on a rear face of the display panel 100. The rear stack structure 400 may include a polymer film layer 410 disposed on the rear face of the display panel 100.

The polymer film layer 410 may include a polymer film. The polymer film layer 410 may include, for example, polyimide (PI), polyethylene terephthalate (PET), polycarbonate (PC), polyethylene (PE), polypropylene (PP), polysulfone (PSF), polymethyl methacrylate (PMMA), triacetyl cellulose (TAC), cycloolefin polymer (COP), etc.

The polymer film layer 410 may include a functional layer on at least one face thereof. The functional layer may include, for example, a light absorbing layer. The light absorbing layer may include a light absorbing material such as black pigment or dye. The light absorption layer may be formed on the polymer film by coating or printing black ink thereon.

The rear stack structure 400 may include a rear bonding member 451 for bonding stacked members adjacent thereto to each other. For example, the first rear bonding member 451 is disposed between the display panel 100 and the polymer film layer 410 to bond the display panel 100 and the polymer film layer 410 to each other.

In one embodiment, a barrier member 420 may be disposed on a rear face of the polymer film layer 410. The barrier member 420 may prevent foreign substances from an outside from entering the display module 10. The barrier member 420 may be made of a material having a variable length according to folding and unfolding operations of the display device 1.

The display device 1 according to one embodiment may include the metal plate 200 disposed on a rear face of the display module 10. That is, the metal plate 200 may be disposed on a rear face of the barrier member 420, and the metal plate 200 may include a grid pattern including bars BAR and slits SLT defined by the bars BAR, so that at least a portion of the metal plate may be constructed to be stretchable.

The barrier member 420 and the metal plate 200 as above-described may be bonded to the rear face of the display module 10 via a first bonding member 510 and a second bonding member 520, respectively.

Specifically, the second bonding member 520 may be disposed between the polymer film layer 410 and the barrier member 420 to bond the polymer film layer 410 and the barrier member 420 to each other. Further, the first bonding member 510 may be disposed between the barrier member 420 and the metal plate 200 to bond the barrier member 420 and the metal plate 200 to each other.

Referring to FIG. 5, in one embodiment, the metal plate 200 may include a first plate portion 210, a second plate portion 220, and a connection portion 230.

The first plate portion 210 and the second plate portion 220 may be arranged in the second direction DR2. The first plate portion 210 and the second plate portion 220 may be symmetrically arranged with each other with respect to the bendable portion FA. That is, the first plate portion 210 and the second plate portion 220 may be spaced apart from each other in the second direction DR2 while the bendable portion FA is interposed therebetween. However, the disclosure is not limited thereto.

In one embodiment, the first plate portion 210 may be disposed to overlap with the first non-bendable portion NFA1. The second plate portion 220 may be disposed to overlap the second non-bendable portion NFA2. Accordingly, the first plate portion 210 and the second plate portion 220 may maintain flatness thereof regardless of the folding operation of the display device 1.

Each of the first plate portion 210 and the second plate portion 220 may have a rectangular shape in plan view. However, the disclosure is not limited thereto. In one embodiment, each of the first plate portion 210 and the second plate portion 220 may maintain a length or a size thereof while not being stretched when the display device 1 is folded.

The connection portion 230 may be disposed between the first plate portion 210 and the second plate portion 220. The connection portion 230 may be disposed to overlap the bendable portion FA. The connection portion 230 may be disposed to overlap with the first folding line FL1 and the second folding line FL2 extending in the first direction DR1 in the thickness direction.

The connection portion 230 may have flexibility. The connection portion 230 may be stretched or compressed when the metal plate 200 is folded or unfolded. The connection portion 230 may have higher elasticity than that of each of the first plate portion 210 and/or the second plate portion 220. The connection portion 230 may reduce tensile or compressive stress caused when the metal plate 200 is bent.

The connection portion 230 may include the grid pattern. That is, the grid pattern may include the bars BAR and slits SLT defined by the bars BAR. Each of the slits SLT may be a hole extending through the metal plate 200 in the third direction DR3.

That is, adjacent ones of the plurality of bars BAR may be partially spaced apart from each other while the slit SLT is interposed therebetween. The plurality of slits SLT may be spaced apart from each other.

In one embodiment, the bars BAR included in the connection portion 230 may include a vertical bar VBAR extending in the first direction DR1 and a horizontal bar HBAR extending in the second direction DR2.

Since the slit SLT may be defined by adjacent bars BAR, the horizontal bar HBAR may be disposed between neighboring slits SLT to each other in the first direction DR1, and the vertical bar VBAR may be disposed between neighboring slits SLT to each other in the second direction DR2.

Each of the slits SLT may extend in the first direction DR1 parallel to the first folding line FL1 and the second folding line FL2. That is, a length in the first direction DR1 of each of the slits SLT may be larger than a length in the second direction DR2 thereof. Accordingly, each of the slits SLT may have a rectangular shape with long-sides extending in the first direction DR1 and short-sides extending in the second direction DR2, and the long-side of the slit STL may be parallel to the first folding line FL1 and the second folding line FL2. However, a shape of each of the slit SLT is not limited to a rectangular shape.

The grid pattern may include a plurality of slits SLT and thus have flexibility. That is, the grid pattern may be stretched in the second direction DR2 when the display device 1 is folded.

The metal plate 200 may include stainless steel. The stainless steel may include, for example, at least one of iron, chromium, carbon, nickel, silicon, manganese, molybdenum, and alloys thereof. In one embodiment, the metal plate 200 may be made of austenitic stainless steel.

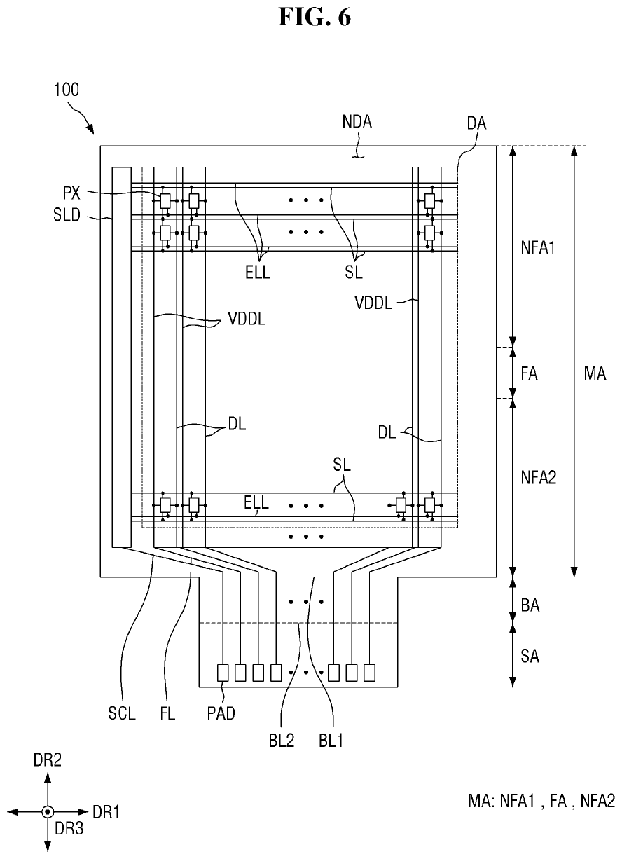

FIG. 6 is a plan view showing a display panel of the display device according to an embodiment of FIG. 1.

In one embodiment, the display panel 100 may include a main area MA, and a bent area BA and a sub-area SA sequentially arranged on one side in the second direction DR2 of main area MA. The main area MA may include the first non-bendable portion NFA1, the bendable portion FA, and the second non-bendable portion NFA2. Descriptions of the first non-bendable portion NFA1, the bendable portion FA, and the second non-bendable portion NFA2 are the same as those as made above in connection with FIG. 1 and FIG. 2, and therefore will be omitted.

The bent area BA may extend from a lower side of the main area MA in a plan view. The bent area BA may be disposed on an upper side of the sub-area SA, and a length in the first direction DR1 of the bent area BA may be shorter than a length in the first direction DR1 of the main area MA of the display panel 100.

However, the disclosure is not limited thereto, and in some embodiments, the length in the first direction DR1 of the bent area BA may be substantially the same as the length in the first direction DR1 of the main area MA of the display panel 100.

The bent area BA may be bent in the third direction DR3 and along a first bending line BL1 positioned at an upper side of the bent area BA.

The sub-area SA may extend from a lower side of the bent area BA in a plan view. A length in the first direction DR1 of the sub-area SA may be substantially the same as a length in the first direction DR1 of the bent area BA. The sub-area SA may be bent in the third direction DR3 and along a second bending line BL2 positioned at the lower side of the bent area BA.

A plurality of pads PAD electrically connected to a circuit board providing a control signal to the display device 1 may be disposed in the sub-area SA.

The display area DA and the non-display area NDA of the display panel 100 may be the same as the display area DA and the non-display area NDA of the first non-bendable portion NFA1, the bendable portion FA, and the second non-bendable portion NFA2 as described above.

The display area DA of the display panel 100 is disposed in the main area MA. Specifically, the display area DA may be disposed in an inner portion excluding an edge portion of the main area MA.

A portion around the display area DA may be the non-display area NDA. That is, the remaining portion of the display panel 100 excluding the display area DA may be the non-display area NDA of the display panel 100.

In some embodiments, a portion of the main area MA around the display area DA, the bent area BA, and the sub-area SA may constitute the non-display area NDA. However, the disclosure is not limited thereto. Each of the bent area BA and the sub-area SA may include the display area DA.

A plurality of pixels PX, and first driving voltage lines VDDL, data lines DL, scan lines SL, and light-emission lines ELL connected to the plurality of pixels PX may be disposed in the display area DA.

Each of the first driving voltage lines VDDL may serve to supply driving voltage to the pixel PX.

In some embodiments, the first driving voltage lines VDDL may extend in and along the display area DA in the second direction DR2 and may be spaced apart from each other in the first direction DR1 and may extend in a parallel manner to each other.

The first driving voltage lines VDDL extending in the parallel manner to each other and in the first direction DR1 and in and along the display area DA may be connected to each other in the non-display area NDA. Although not shown in the drawings, in some embodiments, a driving voltage line extending along the first direction DR1 and connected to the first driving voltage line VDDL may be further disposed in the display area DA.

The data lines DL may provide a data signal to the pixels PX. In some embodiments, the data lines DL may extend along the second direction DR2, and may be spaced apart from each other in the first direction DR1 and may extend in a parallel manner to each other and may extend in a parallel manner to the first driving voltage lines VDDL.

The scan lines SL may serve to provide a scan signal to the pixels PX. In some embodiments, the scan lines SL may extend in the first direction DR1 and in a parallel manner to each other and may intersect the first driving voltage lines VDDL and the data lines DL.

The light-emission lines ELL may serve to provide voltage required for light emission to the pixels PX. In some embodiments, the light-emission lines ELL may extend in the first direction DR1 and in a parallel manner to each other and in the parallel manner to the scan lines SL.

The pixel PX may receive signals from the first driving voltage line VDDL, the data line DL, the scan line SL, and the light-emission line ELL and may emit light to output an image from the display area DA. Each of the pixels PX may be connected to the first driving voltage line VDDL, at least one of the scan lines SL, one of the data lines DL, and at least one of the light-emission lines ELL.

FIG. 6 illustrates that each of the pixels PX is connected to two scan lines SL, one data line DL, one light-emission line ELL, and the first driving voltage line VDDL. However, the disclosure is not limited thereto. In some embodiments, each of the pixels PX may be connected to three scan lines SL instead of two scan lines SL.

A scan driver SLD, a fan-out line FL, and the pads PAD may be disposed in the non-display area NDA.

The scan driver SLD may serve to apply the scan signal to the scan lines SL and apply a light-emission signal to the light-emission lines ELL. The scan driver SLD may be disposed along one side in the non-display area NDA of the main area MA. However, the disclosure is not limited thereto. For example, the scan driver SLD may be disposed at two sides separated in the first direction DR1 of the non-display area NDA of the main area MA. Although not shown in the drawing, the scan driver SLD may include a scan signal output unit and a light-emission signal output unit. The scan signal output unit may generate scan signals and sequentially output the scan signals to the scan lines SL. The light-emission signal output unit may generate light-emission signals and sequentially output the light-emission signals to light-emission lines ELL.

The scan driver SLD may receive a scan control signal and a light-emission control signal through a scan control line SCL. Although electrical connection between the scan control line SCL and a display driving circuit is not shown in the drawing, the scan control line SCL may be electrically connected to the display driving circuit and receive the scan control signal and the light-emission control signal therefrom.

The fan-out line FL may serve to electrically connect the data line DL to the pad PAD of the sub-area SA. As described above, when a dimension in the first direction DR1 of the sub-area SA is smaller than a dimension in the first direction DR1 of the main area MA, the fan-out line FL may be disposed between the main area MA and the sub-area SA and may converge toward a center in the first direction DR1 of the sub-area SA.

The pad PAD may be electrically connected to the circuit board to be described later, and may serve to receive a control signal from the circuit board and transmit the control signal to the display panel 100. The plurality of pads PAD may be disposed at one side in the sub-area SA. For example, the pads PAD may be arranged side by side and may be spaced from each other by a predefined spacing in the first direction DR1.

Although not shown in FIG. 6, the display device 1 may further include the circuit board, and the pad PAD and the circuit board may be electrically connected to each other. The circuit board may serve to supply a power signal and various control signals to the display panel 100. The circuit board may be disposed at one side of the display panel 100, for example at the side closest to the pads PAD that are in the sub-area SA and may be electrically connected to the pad PAD.

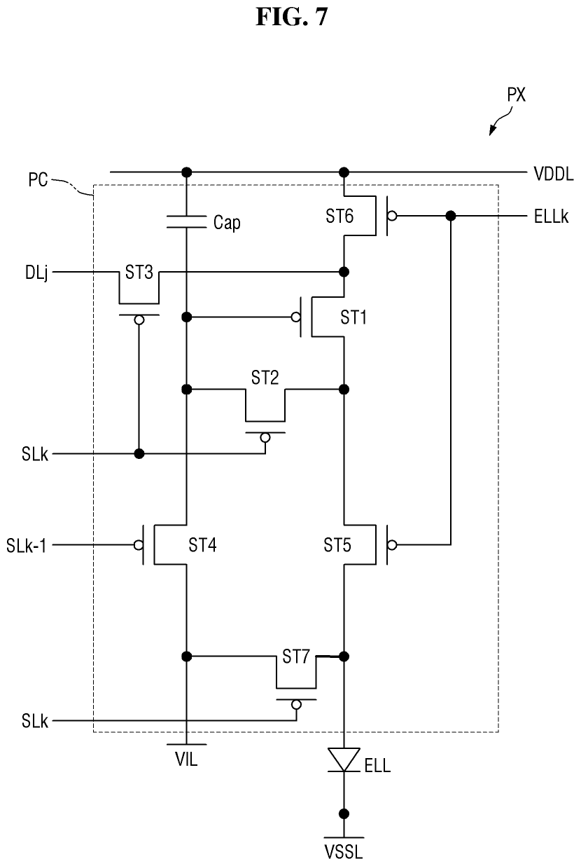

FIG. 7 is a circuit diagram for illustrating a circuit structure of the pixel.

Referring to FIG. 7, the pixels PX disposed in the display area DA (in FIG. 6) of the display panel 100 may be connected to a (k−1)-th scan line SLk−1, a k-th scan line SLk and a j-th data line DLj. Each of k and j may be a natural number of 1 or larger.

Further, the pixel PX may be connected to the first driving voltage line VDDL receiving a first driving voltage, an initialization voltage line VIL receiving an initialization voltage, and a second driving voltage line VSSL to which a second driving voltage having a voltage value lower than the first driving voltage is supplied.

The pixels PX disposed in the display area DA (in FIG. 6) may be classified into a first pixel PX1 which is disposed in an area where the display panel 100 and the bar BAR included in the connection portion 230 of the metal plate 200 overlap each other, and a second pixel PX2 disposed in an area in which the display panel 100 and the slit SLT included in the connection portion 230 of the metal plate 200 overlap each other.

The pixel PX includes a pixel circuit PC including a plurality of thin-film transistors and a light-emitting element EL. The pixel circuit PC includes a driving thin-film transistor DT and a switching thin-film transistor SW. The driving thin-film transistor DT may receive the first driving voltage or the second driving voltage and may supply driving current to the light-emitting element EL. The switching thin-film transistor SW may transmit the data signal to the driving thin-film transistor DT.

The pixel circuit PC may include the driving thin-film transistor DT including a first thin-film transistor ST1, and a switching thin-film transistors SW including a second thin-film transistor ST2, a third thin-film transistor ST3, a fourth thin-film transistor ST4, a fifth thin-film transistor ST5, a sixth thin-film transistor ST6, and a seventh thin-film transistor ST7. In other words, the pixel circuit PC may include a plurality of thin-film transistors, that is, the first thin-film transistor ST1, the second thin-film transistor ST2, the third thin-film transistor ST3, the fourth thin-film transistor ST4, the fifth thin-film transistor ST5, the sixth thin-film transistor ST6 and the seventh thin-film transistor ST7.

Further, the pixel circuits PC may be classified into a first pixel circuit PC1 connected to the first pixel PX1 and the second pixel circuit PC2 connected to the second pixel PX2.

Specifically, the pixel circuit PC connected to the first pixel PX1 may be defined as the first pixel circuit PC1, and the pixel circuit PC connected to the second pixel PX2 may be defined as the second pixel circuit PC2.

The light-emitting element EL may include a first electrode, a second electrode and a light-emitting layer. Further, the light-emitting elements may be classified into a first light-emitting element EL1 and a second light-emitting element EL2 based on a position thereof.

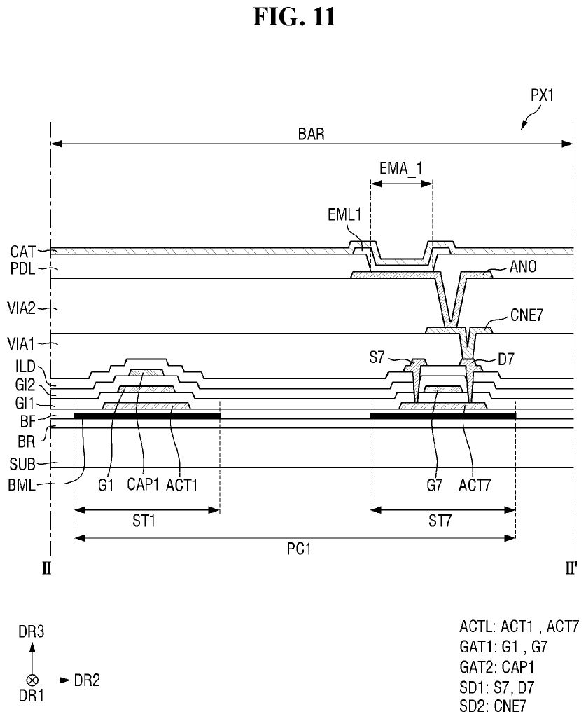

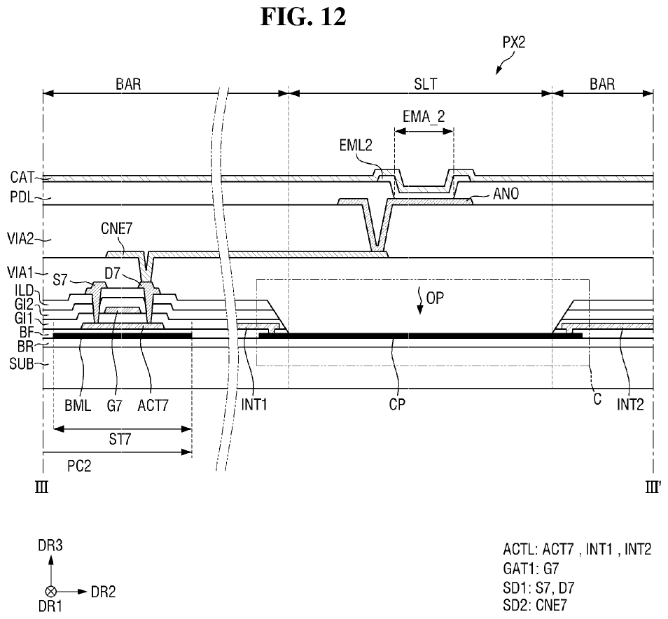

Specifically, as described later in conjunction with FIG. 11 and FIG. 12, the light-emitting element EL disposed in an area in which the display panel 100 and the bar BAR included in the connection portion 230 of the metal plate 200 overlap each other may be defined as the first light-emitting element EL1, while the light-emitting element EL disposed in an area where the display panel 100 and the slit SLT included in the connection portion 230 of the metal plate 200 overlap each other may be defined as the second light-emitting element EL2.

In one example, the light-emitting layer of the light-emitting element may have a light-emitting area defined by a pixel defining film PDL (see FIG. 11), which will be described later. Accordingly, the light-emitting area of the first light-emitting element EL1 may be a first light-emitting area EMA1 (see FIG. 11), while the light-emitting area of the second light-emitting element EL2 may be a second light-emitting area EMA2 (see FIG. 12).

That is, the first pixel PX1 may include the first light-emitting element EL1 and the first pixel circuit PC1 connected to the first light-emitting element EL1 (see FIG. 1I). The second pixel PX2 may include the second light-emitting element EL2 and the second pixel circuit PC2 connected to the second light-emitting element EL2 (see FIG. 12).

In this case, each of the first pixel circuit PC1 and the second pixel circuit PC2 may include the first thin-film transistor ST1 the second thin-film transistor ST2, the third thin-film transistor ST3, the fourth thin-film transistor ST4, the fifth thin-film transistor ST5, the sixth thin-film transistor ST6, and the seventh thin-film transistor ST7 as above-described.

The first thin-film transistor ST1 may include a first gate electrode, a first semiconductor active area, a first electrode, a second electrode, and the like. The first thin-film transistor ST1 controls a drain-source current flowing between the first electrode and the second electrode based on the data voltage applied to the first gate electrode. The driving current flowing through a channel of the first thin-film transistor ST1 is proportional to a square of a difference between a difference (gate-source voltage) between voltages of the first gate electrode and the first electrode of the first thin-film transistor ST1 and a threshold voltage, as in a following Equation 1.

Ids=k′×(Vgs−Vth)² Equation 1

In the above Equation 1, k′ denotes a proportional constant determined based on a structure and physical properties of the first thin-film transistor ST1, Vgs denotes the gate-source voltage of the first thin-film transistor ST1, Vth denotes a threshold voltage of the first thin-film transistor ST1, and Ids denotes the driving current.

The light-emitting element EL may serve to emit light based on the driving current Ids. A light-emission amount of the light-emitting element EL may be proportional to the driving current Ids.

The light-emitting element EL may include the first electrode, the second electrode, and the light-emitting layer EML disposed between the first electrode and the second electrode (see FIG. 11 and FIG. 12).

The first electrode may be an anode electrode, and the second electrode may be a cathode electrode.

The second thin-film transistor ST2 is turned on based on a scan signal of a k-th scan line SLk to connect the first gate electrode and the second electrode of the first thin-film transistor ST1 to each other. That is, when the second thin-film transistor ST2 is turned on, the first gate electrode and the second electrode of the first thin-film transistor ST1 are connected to each other, so that the first thin-film transistor ST1 operates as a diode. The second thin-film transistor ST2 may include a second gate electrode, a second semiconductor active area, a first electrode, and a second electrode. The second gate electrode may be connected to the k-th scan line SLk, the first electrode of the second thin-film transistor ST2 may be connected to the second electrode of the first thin-film transistor ST1, and the second electrode of the second thin-film transistor ST2 may be connected the first gate electrode of the first thin-film transistor ST1.

The third thin-film transistor ST3 is turned on based on a scan signal of the k-th scan line SLk to connect the first electrode of the first thin-film transistor ST1 to a j-th data line DLj. The third thin-film transistor ST3 may include a third gate electrode, a third semiconductor active area, a first electrode, and a second electrode. The third gate electrode of the third thin-film transistor ST3 may be connected to the k-th scan line SLk. The first electrode of the third thin-film transistor ST3 may be connected to the first electrode of the first thin-film transistor ST1, and the second electrode of the third thin-film transistor ST3 may be connected to the j-th data line DLj.

The fourth thin-film transistor ST4 is turned on based on a scan signal of a (k−1)-th scan line SLk−1 to connect the first gate electrode of the first thin-film transistor ST1 and the initialization voltage line VIL to each other. The first gate electrode of the first thin-film transistor ST1 may be discharged into an initialization voltage of the initialization voltage line VIL. The fourth thin-film transistor ST4 may include a fourth gate electrode, a fourth semiconductor active area, a first electrode, and a second electrode. The fourth gate electrode of the fourth thin-film transistor ST4 may be connected to the (k−1)-th scan line SLk−1. The first electrode of the fourth thin-film transistor ST4 may be connected to the first gate electrode of the first thin-film transistor ST1, and the second electrode of the fourth thin-film transistor ST4 may be connected to the initialization voltage line VIL.

The fifth thin-film transistor ST5 may be disposed between and connected to the second electrode of the first thin-film transistor ST1 and the first electrode of the light-emitting element EL. The fifth thin-film transistor ST5 is turned on based on a light-emission control signal of a k-th light-emission line ELLk to connect the second electrode of the first thin-film transistor ST1 and the first electrode of the light-emitting element EL to each other. The fifth thin-film transistor ST5 may include a fifth gate electrode, a fifth semiconductor active area, a first electrode, and a second electrode. The fifth gate electrode of the fifth thin-film transistor ST5 may be connected to the k-th light-emission line ELLk. The first electrode of the fifth thin-film transistor ST5 may be connected to the second electrode of the first thin-film transistor ST1, the second electrode of the fifth thin-film transistor ST5 may be connected to the first electrode of the light-emitting element EL.

The sixth thin-film transistor ST6 is turned on based on the light-emission control signal of the k-th light-emission line ELLk to connect the first electrode of the first thin-film transistor ST1 to the first driving voltage line VDDL. The sixth thin-film transistor ST6 may include a sixth gate electrode, a sixth semiconductor active area, a first electrode, and a second electrode. The sixth gate electrode of the sixth thin-film transistor ST6 may be connected to the k-th light-emission line ELLk. The first electrode of the sixth thin-film transistor ST6 may be connected to the first driving voltage line VDDL, and the second electrode of the sixth thin-film transistor ST6 may be connected to the first electrode of the first thin-film transistor ST1. When both the fifth thin-film transistor ST5 and the sixth thin-film transistor ST6 are turned on, driving current may be supplied to the light-emitting element EL.

The seventh thin-film transistor ST7 is turned on based on the scan signal of the k-th scan line SLk to connect the first electrode of the light-emitting element EL and the initialization voltage line VIL to each other. The first electrode of the light-emitting element EL may be discharged into the initialization voltage. The seventh thin-film transistor ST7 may include a seventh gate electrode, a seventh semiconductor active area, a first electrode, and a second electrode. The seventh gate electrode of the seventh thin-film transistor ST7 may be connected to the k-th scan line SLk. The first electrode of the seventh thin-film transistor ST7 may be connected to the first electrode of the light-emitting element EL, and the second electrode of the seventh thin-film transistor ST7 may be connected to the initialization voltage line VIL.

The pixel circuit PC may further include a capacitor Caps. The capacitor Cap is formed between the first gate electrode of the first thin-film transistor ST1 and the first driving voltage line VDDL. One electrode of the capacitor Cap may be connected to the first gate electrode of the first thin-film transistor ST1, while the other electrode thereof may be connected to the first driving voltage line VDDL.

When the first electrode of each of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 acts as a source electrode, the second electrode thereof may act as a drain electrode.

Alternatively, when the first electrode of each of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 acts as a drain electrode, the second electrode thereof may act as a source electrode.

Each of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistors ST7 may include each semiconductor active area as described above. Each of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 may include a semiconductor active area made of polysilicon. The disclosure is not limited thereto.

When the semiconductor active area of each of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 is made of polycrystalline silicon, a process for forming the semiconductor active area may be a low-temperature polycrystalline silicon process.

Further, in FIG. 7, an example in which each of all of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 is embodied as a p-type thin-film transistor has been described. The disclosure is not limited thereto. Some or all of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 may be embodied as an n-type thin-film transistor.

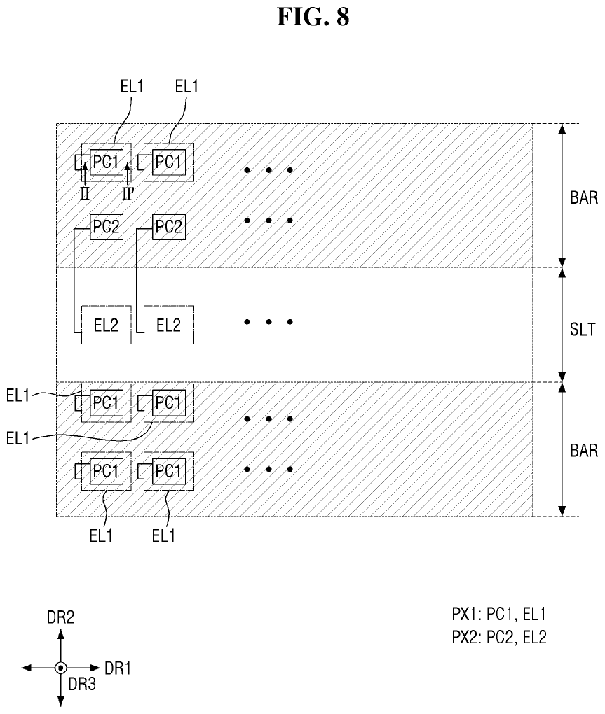

FIG. 8 is a diagram schematically showing an arrangement of the light-emitting element and the pixel circuit disposed in an area A of FIG. 1.

In FIG. 8, in order to illustrate an arrangement relationship between the pixel circuit PC and the light-emitting element EL disposed in the area in which the display panel 100 and the bar BAR and the slit SLT included in the connection portion 230 of the metal plate 200 as described above overlap each other, remaining components are omitted. Thus, FIG. 8 is schematical. Referring to FIG. 8, in one embodiment, the first pixel PX1 may include the first pixel circuit PC1 and the first light-emitting element EL1. The first light-emitting element EL1 may overlap the first pixel circuit PC1. In other words, the first light-emitting element EL1 and the first pixel circuit PC1 may be disposed in the area where the display panel 100 and the bar BAR overlap each other, and may overlap each other.

The first light-emitting element EL1 may have the first light-emitting area EMA1 defined by the pixel defining film PDL (in FIG. 11) to be described later.

The second pixel PX2 may include the second pixel circuit PC2 and the second light-emitting element EL2. The second light-emitting element EL2 may not overlap with the second pixel circuit PC2. In other words, the second light-emitting element EL2 may be disposed only in an area where the display panel 100 and the slit SLT included in the connection portion 230 of the metal plate 200 overlap each other. The second pixel circuit PC2 may be disposed only in an area where the display panel 100 and the bar BAR included in the connection portion 230 of the metal plate 200 overlap each other. Thus, the second light-emitting element EL2 and the second pixel circuit PC2 may not overlap each other and may be electrically connected to each other via a seventh connection electrode CNE7 (see FIG. 12), which will be described later.

That is, only the second light-emitting element EL2 may be disposed in the area where the display panel 100 and the slit SLT overlap each other. The first light-emitting element EL1, the first pixel circuit PC1, and the second pixel circuit PC2 except for the second light-emitting element EL2 may be disposed in the area where the display panel 100 and the bar BAR overlap each other.

In one embodiment, a spacing between the second light-emitting elements EL2 may be relatively larger than a spacing between the first light-emitting elements EL1. Accordingly, a density of the pixels PX disposed in the area where the display panel 100 and the bar BAR included in the connection portion 230 of the metal plate 200 overlap each other may be relatively higher than a density of the pixels PX disposed in the area wherein the display panel 100 and the slit SLT included in the connection portion 230 of the metal plate 200 overlap each other. However, the disclosure is not limited thereto.

As described above, the light-emitting element EL, but not the pixel circuit PC, is disposed in the area where the display panel 100 and the slit SLT overlap each other. In this case, when the display device 1 is bent, deterioration of the pixel circuit PC may be prevented and flexibility of the slit SLT included in the connection portion 230 of the metal plate 200 may be improved, so that the display device 1 may be bent more easily.

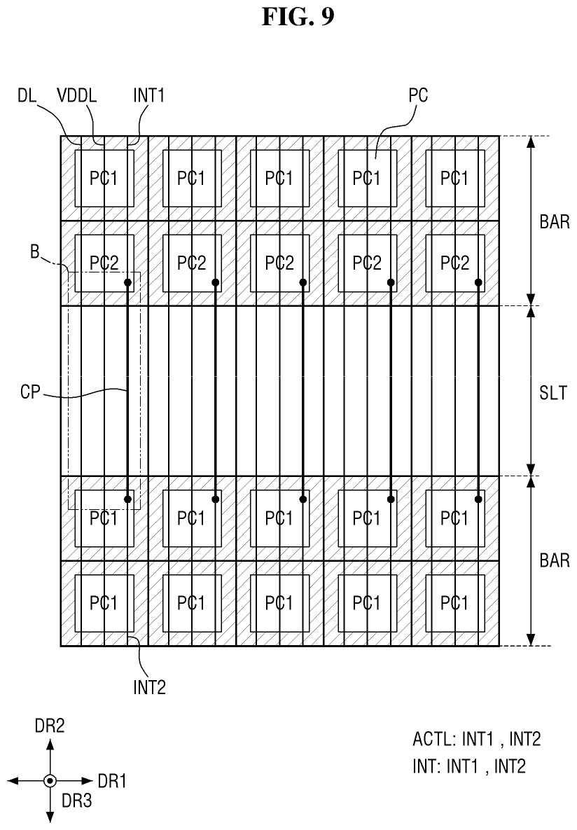

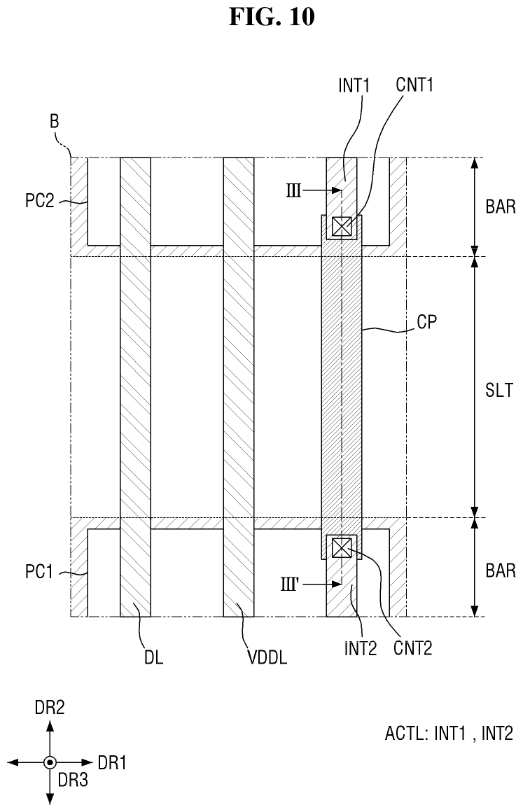

FIG. 9 is a diagram schematically showing an arrangement of pixel circuits and lines disposed in the area A of FIG. 1. FIG. 10 is an enlarged view of an area B of FIG. 9.

In FIG. 9 and FIG. 10, for convenience of illustration, illustration of the pixels PX disposed in the area in which the display panel 100 and the bar BAR and the slit SLT included in the connection portion 230 of the metal plate 200 is omitted. Rather, FIG. 9 and FIG. 10 schematically show an arrangement of the pixel circuit PC and the data line DL, the first driving voltage line VDDL, the initialization line INT, and the connection line CP. Other lines may be further included therein.

The arrangement of the first pixel circuit PC1 and the second pixel circuit PC2 shown in FIG. 9 and FIG. 10 is illustrative. The disclosure is not limited thereto. In some embodiments, the arrangement of the first pixel circuit PC1 and the second pixel circuit PC2 may be modified.

Referring to FIG. 9, as described above, in one embodiment, the pixel circuits PC are disposed only in the area where the display panel 100 and the bar BAR included in the connection portion 230 of the metal plate 200 overlap each other, and the pixel circuit PC is not disposed in the area where the display panel 100 and the slit SLT included in the connection portion 230 of the metal plate 200 overlap each other.

Further, as described above, the data line DL, the first driving voltage line VDDL, the initialization line INT, and the connection line CP may be connected to the pixel (not shown) and may be disposed in the area where the bar BAR and the slit STL included in the connection portion 230 of the metal plate 200 and the display panel 100 overlap each other.

As shown in FIG. 9, the data lines DL may extend along the second direction DR2 and may be connected to the pixel circuits PC adjacent to each other in the second direction DR2.

Specifically, the data line DL may be connected to the first pixel circuit PC1 and the second pixel circuit PC2 adjacent to each other in the second direction DR2 and disposed on the upper bar BAR among the bars BAR spaced apart from each other while the slit SLT is interposed therebetween, and may extend along the second direction DR2, and may connect the second pixel circuit PC2 positioned on the upper bar BAR and the first pixel circuit PC1 positioned on a lower bar BAR to each other, and may extend along and across the slit SLT where no pixel circuit PC is disposed along the second direction DR2.

Further, the data line DL may be connected to the first pixel circuits PC1 adjacent to each other in the second direction DR2 and disposed on the lower bar BAR and may extend along the second direction DR2 and may provide the data signal to pixels (not shown) disposed on the bar BAR and the slit SLT.

In one embodiment, the data line DL may include one or more metals selected from aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). The data line DL may be embodied as a single layer or a multilayer layer.

The first driving voltage line VDDL may be spaced apart from the data line DL in the first direction DR1 and may extend in a parallel manner to the data line DL.

Specifically, the first driving voltage line VDDL may be spaced apart from the data line DL in the first direction DR1 and may be parallel thereto. As in the data line DL as described above, the first driving voltage line VDDL may be connected to the first pixel circuit PC1 and the second pixel circuit PC2 adjacent to each other in the second direction DR2 and disposed on the upper bar BAR among the bars BAR spaced apart from each other while the slit SLT is interposed therebetween, and may extend along the second direction DR2, and may connect the second pixel circuit PC2 positioned on the upper bar BAR and the first pixel circuit PC1 positioned on the lower bar BAR to each other, and may extend along and across the slit SLT where no pixel circuit PC is disposed along the second direction DR2.

Further, the first driving voltage line VDDL may be connected to the first pixel circuits PC1 adjacent to each other in the second direction DR2 and disposed on the lower bar BAR and may extend along the second direction DR2 and may provide the driving voltage to pixels (not shown) disposed on the bar BAR and the slit SLT.

In one embodiment, the first driving voltage line VDDL may be composed of a single film or a multilayer film, and may be made of the same material as that of the data line DL. However, the disclosure is not limited thereto.

In FIG. 9 and FIG. 10, the initialization line INT is briefly illustrated such that the initialization line INT extends in a parallel manner to the data line DL and the first driving voltage line VDDL and is disposed in the same layer as a layer in which data line DL and the first driving voltage line VDDL are disposed and extends in the second direction DR2. However, the disclosure is not limited thereto. The initialization line INT may be disposed on a different layer from a layer in which the data line DL and the first driving voltage line VDDL are disposed.

Whereas each of the data line DL and the first driving voltage line VDLL extends along the second direction DR2 and extends continuously across the upper bar BAR, the slit SLT, and the lower bar BAR, the initialization line INT may include a first portion INT1 and a second portion INT2 spaced apart from each other while the slit SLT is interposed therebetween.

The second portion INT2 of the initialization line INT may coincide with an imaginary line extending from the first portion INT1 in the second direction DR2. That is, the imaginary line extending from the first portion INT1 in the second direction DR2 may coincide with an imaginary line extending from the second portion INT2 in the second direction DR2.

Specifically, the first portion INT1 of the initialization line INT1 may be disposed on the upper bar BAR disposed on an upper side of the slit SLT in a plan view, while the second portion INT2 may be disposed on the lower bar BAR disposed on a lower side of the slit SLT in a plan view.

The connection line CP may extend along the second direction DR2 and along and across the upper bar BAR disposed on an upper side of the slit SLT, the slit SLT, and the lower bar BAR disposed on a lower side of the slit SLT and may electrically connect the first portion INT1 and the second portion INT2 to each other.

Specifically, the connection line CP may be connected to an end of the first portion INT1 of the initialization line INT disposed in the upper bar BAR disposed on an upper side of the slit SLT in a plan view. The connection line CP may extend along the second direction DR2. The connection line CP may extend along and across the slit SLT and may be connected to an end of the second portion INT2 of the initialization line INT disposed in the lower bar BAR disposed on the lower side of the slit SLT in a plan view. Thus, the connection line CP may electrically connect the first portion INT1 and the second portion INT2 to each other.

That is, an end of the first portion INT1 of the initialization line INT disposed in the upper bar BAR may be electrically connected to an end of the connection line CP disposed in the upper bar area BAR disposed on an upper side of the slit via a first contact hole CNT1. An end of the second portion INT2 of the initialization line INT positioned in the lower bar BAR may be electrically connected to an end of the connection line CP positioned in the lower bar area BAR via a second contact hole CNT2.

In one embodiment, the initialization line INT may be disposed in the same layer as a semiconductor layer ACTL (see FIG. 11) which will be described later in a cross sectional view of the display panel 100, and may include the same material as that of the semiconductor layer ACTL. For example, the initialization line INT may include a binary compound (ABₓ), a ternary compound (ABₓC_{y}), and a quaternary compound (ABₓC_{y}D_{z}) containing indium, zinc, gallium, tin, titanium, aluminum, hafnium (Hf), zirconium (Zr), magnesium (Mg), etc.

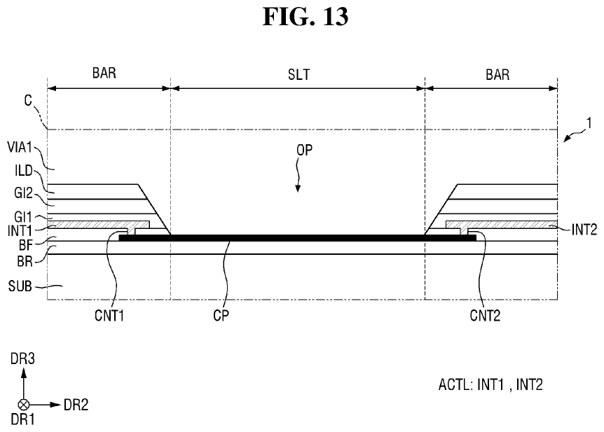

Further, in one embodiment, the connection line CP may be disposed in a different layer from a layer in which the initialization line INT is disposed, and may include a material different from that of the initialization line INT. A detailed description of the arrangement of the connection line CP and the material included in the connection line CP will be described later in conjunction with FIG. 12 and FIG. 13.

Although not shown in FIG. 9 and FIG. 10, in one embodiment, the scan lines SL may be disposed in the area in which the bar BAR and the slit SLT included in the connection portion 230 of the metal plate 200 and the display panel 100 overlap each other and may extend in the first direction DR1. The scan lines SL may intersect the data line DL, the first driving voltage line VDDL, the initialization line INT, and the connection line CP extending in the second direction DR2.

Specifically, the scan lines SL may extend in the first direction DR1 and may be disposed on the bar BAR, but may not be disposed on the slit SLT. However, the disclosure is not limited thereto, and in some embodiments, the scan lines SL may be disposed on the bar BAR and the slit SLT.

In one embodiment, the data line DL and the first driving voltage line VDDL may be disposed in the same layer and may include the same material. The first portion INT1 and the second portion INT2 of the initialization line INT may be portions of the semiconductor layer ACTL as described above and may be disposed in a different layer from a layer in which the data line DL and the first driving voltage line VDDL are disposed. The first portion INT1 and the second portion INT2 of the initialization line INT may include a material different from that of each of the data line DL and the first driving voltage line VDDL.

In this way, as the first portion INT1 and the second portion INT2 of the initialization line INT includes a material different from that of each of the data line DL and the first driving voltage line VDDL, the initialization line INT having smaller stretchability or elongation may be removed from the slit SLT included in the connection portion 230 of the metal plate 200, and rather, the connection line CP with larger stretchability or elongation than that of the initialization line INT may be disposed on the slit SLT, thereby preventing the initialization line INT from being discontinuous due to an external impact to the display panel 100 or when the display device 1 is bent.

Hereinafter, a stack structure of the display panel 100 will be described in detail.

FIG. 11 is a cross-sectional view schematically showing a cross-section taken along a line II-II′ of FIG. 8 according to one embodiment.

FIG. 11 depicts a cross-sectional area between the bar BAR included in the connection portion 230 of the metal plate 200 and the display panel 100. According to one embodiment, the display panel 100 may include a sequential stack that includes a substrate SUB, a barrier layer BR, a lower metal layer BML, a buffer layer BF, the semiconductor layer ACTL, a first gate insulating layer GI1, a first gate conductive layer GAT1, a second gate insulating layer GI2, a second gate conductive layer GAT2, an inter insulating layer ILD, a first metal conductive layer SD1, a first via insulating layer VIA1, a second metal conductive layer SD2, a second via insulating layer VIA2, the pixel defining film PDL, and the first light-emitting element EL1 disposed along the third direction DR3.

For convenience of illustration, FIG. 11 shows only the first thin-film transistor ST1 and the seventh thin-film transistor ST7 of the first pixel circuit PC1.

The substrate SUB may serve as a basis of the display panel 100. When the substrate SUB is a flexible substrate SUB having flexibility, the substrate SUB may include, but is not limited to, polyimide.

Further, when the substrate SUB is a rigid substrate SUB having rigidity, the substrate SUB may include, but is not limited to, glass. Hereinafter, for the convenience of description, an example in which the substrate SUB is embodied as the flexible substrate SUB with flexibility including polyimide will be described. However, the disclosure is not limited thereto.

The barrier layer BR prevents penetration of an external foreign material into the panel and may be a single layer or multiple layers including an inorganic material such as silicon nitride (SiNₓ) or silicon oxide (SiOₓ).

The lower metal layer BML may be partially disposed on the barrier layer BR.

Specifically, the lower metal layer BML may be disposed in a corresponding manner to a bottom of each of the first thin-film transistor ST1 and the seventh thin-film transistor ST7 of the first pixel circuit PC1, and may prevent external light from reaching the first pixel PX1.

In some embodiments, a constant voltage or signal may be applied to the lower metal layer BML to prevent damage to the first pixel circuit PC1 or to prevent deterioration of the first pixel circuit PC1 due to static electricity discharge.

In one embodiment, the lower metal layer BML may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The lower metal layer BML may be a single layer or multiple layers made of the aforementioned material. However, the disclosure is not limited thereto.

The buffer layer BF may be disposed on the barrier layer BR, and may cover an entirety of the lower metal layer BML.

The buffer layer BF may serve to prevent diffusion of metal atoms or impurities from the substrate SUB to the semiconductor layer ACTL. The buffer layer BF may be disposed over an entirety of the substrate SUB. The buffer layer BF may include an inorganic insulating material (SiOₓN_{y}).

The semiconductor layer ACTL may include the semiconductor active area of each of the first thin-film transistor ST1, the second thin-film transistor ST2, the third thin-film transistor ST3, the fourth thin-film transistor ST4, the fifth thin-film transistor ST5, the sixth thin-film transistor ST6, and the seventh thin-film transistor ST7 of the first pixel circuit PC1.

For example, as shown in FIG. 11, the first thin-film transistor ST1 of the first pixel circuit PC1 includes a first semiconductor active area ACT1, and the seventh thin-film transistor ST7 thereof includes a seventh semiconductor active area ACT7.

The first semiconductor active area ACT1 may include a first channel area overlapping with a first gate electrode GI to be described later, a first drain area disposed on one side of the first channel area, and a first source disposed on the other side of the first channel area. The seventh semiconductor active area ACT7 may include a seventh channel area overlapping a seventh gate electrode G7 which will be described later, a seventh drain area disposed on one side of the seventh channel area, and the seventh source area disposed on the other side of the seventh channel area.

The semiconductor layer ACTL may be disposed directly on one face of the buffer layer BF. That is, the semiconductor layer ACTL may directly contact one face of the buffer layer BF. The semiconductor layer ACTL may be selectively patterned and disposed on the buffer layer BF. In some embodiments, the semiconductor layer ACTL may include, but is not limited to, polycrystalline silicon. For example, the semiconductor layer ACTL may include an amorphous silicon or oxide semiconductor.

The first gate insulating layer GI1 may electrically insulate the semiconductor layer ACTL and the first metal conductive layer SDI to be described later from each other. The first gate insulating layer GI1 may be disposed on the buffer layer BF on which the semiconductor layer ACTL has been disposed so as to cover the semiconductor layer ACTL. The first gate insulating layer GI1 may be conformal to the semiconductor layer ACTL. In some embodiments, the first gate insulating layer GI1 may include an inorganic insulating material (SiOₓN_{y}).

The first metal conductive layer SD1 may be disposed on the first gate insulating layer GI1. The first metal conductive layer SDI may be disposed directly on one face of the first gate insulating layer GI1. That is, the first metal conductive layer SD1 may directly contact one face of the first gate insulating layer GI1.

The first gate conductive layer GAT1 may include the gate electrode of each of the first thin-film transistor ST1, the second thin-film transistor ST2, the third thin-film transistor ST3, the fourth thin-film transistor ST4, the fifth thin-film transistor ST5, the sixth thin-film transistor ST6 and the seventh thin-film transistor ST7 of the first pixel circuit PC1.

For example, as shown in FIG. 11, the first gate conductive layer GAT1 may include the first gate electrode G1 of the first thin-film transistor ST1 and the seventh gate electrode G7 of the seventh thin-film transistor ST7. As described above, the first gate electrode G1 and the seventh gate electrode G7 may overlap the first channel area of the first semiconductor active area ACT1, and the seventh channel area of the seventh semiconductor active area ACT7 in the third direction DR3, respectively.

The first gate conductive layer GAT1 may include metal. For example, the first gate conductive layer GAT1 may include aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The second gate insulating layer GI2 may electrically insulate the first gate conductive layer GAT1 and the second gate conductive layer GAT2 to be described later from each other. The second gate insulating layer GI2 may be disposed on the first gate insulating layer GI1 on which the first gate conductive layer GAT1 has been disposed so as to cover the first gate conductive layer GAT1. The second gate insulating layer GI2 may be formed in a substantially uniform thickness and may be disposed along a profile of the first gate conductive layer GAT1. In some embodiments, the second gate insulating layer GI2 may include an inorganic insulating material (SiOₓN_{y}).

The second gate conductive layer GAT2 may be disposed on the second gate insulating layer GI2. The second gate conductive layer GAT2 may be positioned directly on one face of the second gate insulating layer GI2. That is, the second gate conductive layer GAT2 may directly contact one face of the second gate insulating layer GI2.

The second gate conductive layer GAT2 may include a capacitor electrode. For example, as shown in FIG. 11, the second gate conductive layer GAT2 may include a first capacitor electrode CAP1 of the first thin-film transistor ST1. The same voltage as a voltage applied to the first driving voltage line VDDL (in FIG. 9) may be applied to the first capacitor electrode CAP1. The first capacitor electrode CAP1 together with the first gate electrode GI and the second gate insulating layer GI2 may constitute the capacitor Cap (see FIG. 7). The first capacitor electrode CAP1 may overlap the first gate electrode GI in the third direction DR3.

The second gate conductive layer GAT2 may include metal. For example, the second gate conductive layer GAT2 may include aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The inter insulating layer ILD may electrically insulate the second gate conductive layer GAT2 and the first metal conductive layer SD1 to be described later from each other. The inter insulating layer ILD may be disposed on the second gate insulating layer G12 on which the second gate conductive layer GAT2 has been formed. The inter insulating layer ILD may include an inorganic insulating material (SiOₓN_{y}).

The first metal conductive layer SDI may be disposed on the inter insulating layer ILD. The first metal conductive layer SD1 may include the source electrode and the drain electrode of each of the first thin-film transistor ST1, the second thin-film transistor ST2, the third thin-film transistor ST3, the fourth thin-film transistor ST4, the fifth thin-film transistor ST5, the sixth thin-film transistor ST6 and the seventh thin-film transistor ST7 of the first pixel circuit PC1. For example, the first metal conductive layer SDI may include a seventh source electrode S7 and a seventh drain electrode D7 of the seventh thin-film transistor, as shown in FIG. 11.

When the first metal conductive layer SD1 is disposed on the inter insulating layer ILD so as to constitute the source electrode and the drain electrode, each of the first thin-film transistor ST1, the second thin-film transistor ST2, the third thin-film transistor ST3, the fourth thin-film transistor ST4, the fifth thin-film transistor ST5, the sixth thin-film transistor ST6 and the seventh thin-film transistor ST7 of the first pixel circuit PC1 may be defined. The seventh source electrode S7 and the seventh drain electrode D7 may be electrically connected to a source area and a drain area via contact holes extending through the first inter insulating layer ILD, the second gate insulating layer GI2 and the first gate insulating layer GI1, respectively.

The first metal conductive layer SDI may include metal. For example, the first metal conductive layer SDI may include aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). In some embodiments, the first metal conductive layer SDI may have a multi-layer structure. For example, the first metal conductive layer SD1 may have a two-layer structure of Ti/Al or a three-layer structure of Ti/Al/Ti.

The first via insulating layer VIA1 may partially electrically insulate the first metal conductive layer SD1 and the second metal conductive layer SD2 to be described later from each other and may serve to planarize a step formed by an element of the first pixel circuit PC1. The first via insulating layer VIA1 may be disposed on the inter insulating layer ILD on which the first metal conductive layer SD1 has been formed. The first via insulating layer VIA1 may be made of organic insulating material such as acryl-based resin, polyimide-based resin, or polyamide-based resin.

The second metal conductive layer SD2 may be disposed on the first via insulating layer VIA1. The second metal conductive layer SD2 may include the initialization voltage line and the connection electrode electrically connected to the source electrode or the drain electrode of each of the first thin-film transistor ST1, the second thin-film transistor ST2, the third thin-film transistor ST3, the fourth thin-film transistor ST4, the fifth thin-film transistor ST5, the sixth thin-film transistor ST6 and the seventh thin-film transistor ST7 of the first pixel circuit PC1.

For example, the second metal conductive layer SD2 may include the seventh connection electrode CNE7 electrically connected to the seventh drain electrode D7 as shown in FIG. 11. The seventh connection electrode CNE7 may be electrically connected to the seventh drain electrode D7 via a contact hole extending through the first via insulating layer VIA1.

The second metal conductive layer SD2 may include metal. For example, the second metal conductive layer SD2 may include aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). In some embodiments, the second metal conductive layer SD2 may have a multi-layer structure. For example, the second metal conductive layer SD2 may have a two-layer structure of Ti/Al or a three-layer structure of Ti/Al/Ti.

The second via insulating layer VIA2 may be disposed on the first via insulating layer VIA1 on which the second metal conductive layer SD2 has been formed. The second via insulating layer VIA2 may be made of an organic insulating material such as acryl-based resin, polyimide-based resin, or polyamide-based resin. One side face in the third direction DR3 of the second via insulating layer VIA2 may be a top face thereof on which the pixel defining film PDL is disposed, while the other side face in the third direction DR3 thereof may be a bottom face thereof on which the first via insulating layer VIA1 is disposed.

The first light-emitting element EL1 (see FIG. 8) may include an anode electrode ANO, the first light-emitting layer EML1 and a cathode electrode CAT, and may be disposed on the second via insulating layer VIA2.

As shown in FIG. 11, the anode electrode ANO of the first light-emitting element EL1 may be electrically connected to the seventh connection electrode CNE7 via a contact hole extending through the second via insulating layer VIA2 and thus may be electrically connected to the seventh drain electrode D7 of the seventh thin-film transistor ST5.

The pixel defining film PDL may be disposed on the second via insulating layer VIA2 on which the anode electrode ANO has been disposed. The pixel defining film PDL may be made of an organic material such as acryl-based resin and polyimide-based resin. The pixel defining film PDL may have an opening defined therein partially exposing the anode electrode. The opening may define the first light-emitting area EMA1 of the first light-emitting layer EML1.

The first light-emitting layer EML1 may be disposed on the anode electrode ANO and the pixel defining film PDL. When the first light-emitting layer EML1 is an organic light-emitting layer including an organic material, the first light-emitting element EL1 may be embodied as an organic light-emitting diode. When the first light-emitting layer EML1 include a quantum dot light-emitting layer, the first light-emitting element EL1 may be embodied as a quantum dot light-emitting element. When the first light-emitting layer EML1 includes an inorganic semiconductor, the first light-emitting element EL1 may be embodied as an inorganic light-emitting element. Alternatively, the first light-emitting element EL1 may be embodied as a micro light-emitting diode.

The cathode electrode CAT may be disposed on the first light-emitting layer EML1. The cathode electrode CAT may cover an entirety of the pixel defining film PDL on which the first light-emitting layer EML1 has been formed. In other words, the cathode electrode CAT may be formed in a substantially uniform thickness and may be disposed along a profile of the pixel defining film PDL on which the first light-emitting layer EML1 has been formed.

A thin-film encapsulation layer may be further disposed on the first light-emitting element EL1. The thin-film encapsulation layer may serve to prevent external moisture and oxygen from penetrating into the first light-emitting element EL1.

A touch sensor layer (not shown) may be further disposed on the thin-film encapsulation layer. The touch sensor layer may serve to detect a touch input applied to the display device 1. The touch sensor layer may have a structure in which a conductive layer and an insulating layer are sequentially stacked. The conductive layer of the touch sensor layer may have a mesh-type shape in a plan view.

Hereinafter, a structure of the display panel 100 in the area where the slit SLT included in the connection portion 230 of the metal plate 200 and the display panel 100 overlap each other in the third direction DR3 will be described in detail.

FIG. 12 is a cross-sectional view schematically showing a cross-section taken along a line III-III′ of FIG. 10 according to one embodiment. FIG. 13 is an enlarged view of a C area of FIG. 12 according to one embodiment.

Referring to FIG. 12, the second pixel PX2 may be disposed in an area where the bar BAR and the slit SLT included in the connection portion 230 of the metal plate 200 and the display panel 100 overlap each other in the third direction DR3.

Specifically, the second pixel PX2 includes the second light-emitting element EL2 and the second pixel circuit PC2. The second light-emitting element EL2 is disposed only in the area in which the slit SLT included in the connection portion 230 of the metal plate 200 and the display panel 100 overlap each other in the third direction DR3. The second pixel circuit PC2 is disposed only in the area where the bar BAR included in the connection portion 230 of the metal plate 200 and the display panel 100 overlap each other in the third direction DR3. The second pixel circuit PC2 and the second light-emitting element EL2 may be electrically connected to each other via the seventh connection electrode CNE7 electrically connected to the seventh drain electrode D7 of the second pixel circuit PC2 to be described later.

In other words, the second light-emitting element EL2 of the second pixel PX2 may overlap in the slit SLT in the third direction DR3, and may not overlap in the bar BAR in the third direction DR3. The second pixel circuit PC2 of the second pixel PX2 may overlap with the bar BAR, and may not overlap with the slit SLT in the third direction DR3.

The area where the bar BAR included in the connection portion 230 of the metal plate 200 and the display panel 100 shown in FIG. 12 overlap each other in the third direction DR3 may include a first area where the first pixel PX1 and the first pixel circuit PC1 are disposed and a second area where the second pixel circuit PC2 is disposed.

In FIG. 12, an area in which one bar BAR included in the connection portion 230 of the metal plate 200 and the display panel 100 overlap each other in the third direction DR3 and another area in which another bar BAR included in the connection portion 230 of the metal plate 200 and the display panel 100 overlap each other in the third direction DR3 are spaced apart from each other in the second direction DR2. An area in which the slit SLT included in the connection portion 230 of the metal plate 200 and the display panel 100 overlap each other in the third direction DR3 is interposed between the two bar regions BAR.

For convenience of illustration, in FIG. 12, in one part of an area in which one bar BAR included in the connection portion 230 of the metal plate 200 and the display panel 100 overlap each other in the third direction DR3 and another area in which another bar BAR included in the connection portion 230 of the metal plate 200 and the display panel 100 overlap each other in the third direction DR3, only the seventh transistor ST7 of the second pixel circuit PC2 are shown, while in the other area thereof, only the second portion INT2 of the initialization line INT disposed on the barrier layer BR is shown.

Specifically, an area disposed on one side of an area in which the slit SLT included in the connection portion 230 of the metal plate 200 and the display panel 100 overlap each other in the third direction DR3 may be defined as a first area on which the first pixel PX1 and the first pixel circuit PC1 are disposed. An area disposed on the other side of the area in which the slit SLT included in the connection portion 230 of the metal plate 200 and the display panel 100 overlap each other in the third direction DR3 may be defined as a second area on which the second pixel circuit PC2 is disposed.

That is, an area disposed on a right side (based on FIG. 12) of the area where the slit SLT included in the connection portion 230 of the metal plate 200 and the display panel 100 overlap each other in the third direction DR3 may be the first area on which the first pixel PX1 and the first pixel circuit PC1 are disposed. An area disposed on a left side (based on FIG. 12) of the area where the slit SLT included in the connection portion 230 of the metal plate 200 and the display panel 100 overlap each other in the third direction DR3 may be the second area on which the second pixel circuit PC2 is disposed.

The first area in which the bar BAR included in the connection portion 230 of the metal plate 200 and the display panel 100 overlap each other in the third direction DR3 and in which the first pixel PX1 and the first pixel circuit PC1 are disposed has the same structure as a structure of the display panel 100 in the area as described above where the bar BAR included in the connection portion 230 of the metal plate 200 and the display panel 100 overlap each other in the third direction DR3. Thus, a description thereof will be omitted.

In the second area where the bar BAR included in the connection portion 230 of the metal plate 200 and the display panel 100 overlap each other in the third direction DR3 and in which the second pixel circuit PC2 of the second pixel PX2 is disposed, the substrate SUB, the barrier layer BR, the lower metal layer BML, the buffer layer BF, the semiconductor layer ACTL, the first gate insulating layer GI1, the first gate conductive layer GAT1, the second gate insulating layer GI2, the second gate conductive layer GAT2, the inter insulating layer ILD, the first metal conductive layer SD1, the first via insulating layer VIA1, the seventh connection electrode CNE7, the second metal conductive layer SD2, the second via insulating layer VIA2, the pixel defining film PDL, and cathode electrode CAT are sequentially stacked in the third direction DR3, as shown in FIG. 12. That is, the components other than the seventh connection electrode CNE7 may be substantially the same components of the display panel 100 in the area as described above where the first pixel PX1 is disposed.

Structures of the seventh thin-film transistor ST7 of the second pixel circuit PC2 and the seventh thin-film transistor ST7 of the first pixel circuit PC1 (see FIG. 11) are substantially the same as each other. Thus, detailed descriptions thereof will be omitted.

The seventh connection electrode CNE7 may be additionally disposed on the first via insulating layer VIA1 and at an area adjacent to a boundary line between the area where the slit SLT included in the connection portion 230 of the metal plate 200 and the display panel 100 overlap each other in the third direction DR3 and the area in which the bar BAR included in the connection portion 230 of the metal plate 200 and the display panel 100 overlap each other in the third direction DR3.

In one embodiment, the seventh connection electrode CNE7 of the second pixel circuit PC2 may be made of the same material as that of the seventh connection electrode CNE7 (see FIG. 11) of the first pixel circuit PC1. However, the disclosure is not limited thereto.

The seventh connection electrode CNE7 may serve to electrically connect the second pixel circuit PC2 and the second light-emitting element EL2 to each other.

Specifically, the seventh connection electrode CNE7 may be electrically connected to the seventh drain electrode D7 of the second pixel circuit PC2 via a contact hole extending through the first via insulating layer VIA1. Accordingly, the second light-emitting element EL2 disposed in the area where the slit SLT included in the connection portion 230 of the metal plate 200 and the display panel 100 overlap each other in the third direction DR3 may be electrically connected to the seventh drain electrode D7 of the second pixel circuit PC2 via the seventh connection electrode CNE7.

In the second area in which the bar BAR included in the connection portion 230 of the metal plate 200 and the display panel 100 shown in FIG. 12 overlap each other in the third direction DR3 and in which the second pixel circuit PC2 of the second pixel PX2 is disposed, the first light-emitting element EL1 and the second light-emitting element EL2 are not disposed. Thus, in the second area, a separate element may not be disposed on the second via insulating layer VIA2, but the pixel defining film PDL may be disposed immediately thereon.

Referring to FIG. 12 and FIG. 13, in the area where the slit SLT included in the connection portion 230 of the metal plate 200 and the display panel 100 overlap each other in the third direction DR3, the buffer layer BF, the first gate insulating layer GI1, the second gate insulating layer GI2, and the inter insulating layer ILD may be removed to expose a surface of the connection line CP disposed on the substrate SUB.

That is, an opening OP may be defined in the area where the slit SLT included in the connection portion 230 of the metal plate 200 and the display panel 100 overlap each other in the third direction DR3.

Specifically, the buffer layer BF, the first gate insulating layer GI1, the second gate insulating layer GI2, and the inter insulating layer ILD may be removed in the area in which the slit SLT included in the connection portion 230 of the metal plate 200 and the display panel 100 overlap each other in the third direction DR3, such that a top face of the connection line CP disposed on the substrate SUB may be exposed.

As described above, the plurality of insulating layers may be removed in the area where the slit SLT included in the connection portion 230 of the metal plate 200 and the display panel 100 overlap each other in the third direction DR3 so as to define the opening OP.

Each of both opposing sidewalls of the opening OP may be defined by each of both opposing side faces of a stack of the buffer layer BF, the first gate insulating layer GI1, the second gate insulating layer GI2, and the inter insulating layer ILD. The side faces of the buffer layer BF, the first gate insulating layer GI1, the second gate insulating layer GI2, and the inter insulating layer ILD may be aligned with each other.

The connection line CP may be disposed on the barrier layer BR and in the second area where the bar BAR included in the connection portion 230 of the metal plate 200 and the display panel 100 overlap each other in the third direction DR3 and in which the second pixel circuit PC2 is disposed, the area where the slit SLT included in the connection portion 230 of the metal plate 200 and the display panel 100 overlap each other in the third direction DR3, and the first area in which the bar BAR included in the connection portion 230 of the metal plate 200 and the display panel 100 overlap each other in the third direction DR3 and in which the first pixel PX1 and the first pixel circuit PC1 are disposed. The connection line CP may electrically connect the first portion INT1 of the initialization line INT1 disposed in the second area in which the bar BAR included in the connection portion 230 of the metal plate 200 and the display panel 100 overlap each other in the third direction DR3 and in which the second pixel circuit PC2 is disposed to the second portion INT2 of the initialization line INT disposed in the first area in which the bar BAR included in the connection portion 230 of the metal plate 200 and the display panel 100 overlap each other in the third direction DR3 and in which the first pixel PX1 and the first pixel circuit PC1 are disposed.

In one embodiment, the first portion INT1 of the initialization line INT may be a portion of the seventh semiconductor active area ACT7 of the second pixel circuit PC2 disposed in the second area as described above. However, the disclosure is not limited thereto. In some embodiments, the first portion INT1 of the initialization line INT disposed in the second area may be a portion of one of the first semiconductor active area ACT1, the fifth semiconductor active area ACT5, and the sixth semiconductor active area ACT6 of the second pixel circuit PC2.

Specifically, the first portion INT1 of the initialization line INT is disposed on the buffer layer BF and in the second area where the second pixel circuit PC2 is disposed. The first portion INT1 is electrically connected to a portion of the connection line CP disposed on the barrier layer BR and in the second area via a contact hole extending through the buffer layer BF. The connection line CP is disposed on the barrier layer BR and in the area where the slit SLT included in the connection portion 230 of the metal plate 200 and the display panel 100 overlap each other in the third direction DR3. The connection line CP extends across the area in which the slit SLT included in the connection portion 230 of the metal plate 200 and the display panel 100 overlap each other in the third direction DR3. Then, the connection line CP is electrically connected to the second portion INT2 of the initialization line INT disposed on the buffer layer BF and in the first area in which the bar BAR included in the connection portion 230 of the metal plate 200 and the display panel 100 overlap each other in the third direction DR3 and in which the first pixel PX1 and the first pixel circuit PC1 are disposed.

That is, the second portion INT2 of the initialization line INT may be disposed on the buffer layer BF and in the first area where the first pixel PX1 and the first pixel circuit PC1 are disposed and may be electrically connected to a portion of the connection line CP disposed on the barrier layer BR and in the first area via the contact hole extending through the buffer layer BF.

Therefore, the first portion INT1 and the second portion INT2 of the initialization line INT which is discontinuous in the area where the slit SLT included in the connection portion 230 of the metal plate 200 and the display panel 100 overlap each other in the third direction DR3 may be electrically connected to each other via the connection line CP.

In one embodiment, the second portion INT2 of the initialization line INT may be a portion of the fifth semiconductor active area ACT5 of the first pixel circuit PC1 disposed in the first area. However, the disclosure is not limited thereto, and in some embodiments, the second portion INT2 of the initialization line INT disposed in the first area may be a portion of one of the first semiconductor active area ACT1 and the sixth semiconductor active area ACT6 of the first pixel circuit PC1.

In one embodiment, each of the first portion INT1 and the second portion INT2 of the initialization line INT may include the same material as that of the semiconductor layer ACTL (FIG. 11) disposed in the area in which the bar BAR included in the connection portion 230 of the metal plate 200 and the display panel 100 overlap each other in the third direction DR3.

Further, in one embodiment, the connection line CP may include the same material as that of the lower metal layer BML as described above. However, the disclosure is not limited thereto, and in some embodiments, the connection line CP may include a material different from that of the lower metal layer BML.

The first via insulating layer VIA1 may be disposed in and extend along in the areas in which the bar BAR and the slit SLT included in the connection portion 230 of the metal plate 200 and the display panel 100 overlap each other in the third direction DR3.

The first via insulating layer VIA1 may compensate for a relative step caused when the buffer layer BF, the first gate insulating layer GI1, the second gate insulating layer GI2, and the inter insulating layer ILD are removed in the area where the slit SLT included in the connection portion 230 of the metal plate 200 and the display panel 100 overlap each other in the third direction DR3.

In other words, a dimension in the third direction DR3 (hereinafter, referred to as ‘thickness’) of the first via insulating layer VIA1 may be larger in the area in which the slit SLT included in the connection portion 230 of the metal plate 200 and the display panel 100 overlap each other in the third direction DR3 than in the area where the bars BAR included in the connection portion 230 of the metal plate 200 and the display panel 100 overlap each other in the third direction DR3.

Further, the first via insulating layer VIA1 may fill an inside of the opening OP. A bottom face of the first via insulating layer VIA1 may directly contact a surface of the connection line CP disposed on the substrate SUB as exposed through the opening OP. The sidewall of the opening OP may be defined by the side faces of the stack of the buffer layer BF, the first gate insulating layer GI1, the second gate insulating layer GI2, and the inter insulating layer ILD.

Therefore, the first portion INT1 and the second portion INT2 of the initialization line INT which is made of the same material as that of the semiconductor layer ACTL and thus has low stretchability or elongation may be electrically connected to each other via the connection line CP. Thus, discontinuity of the initialization line INT that may occur in the area where the slit SLT included in the connection portion 230 of the metal plate 200 and the display panel 100 overlap each other in the third direction DR3 when the display device 1 is bent or the display panel 100 is subjected to an external impact may be effectively prevented. Further, the plurality of inorganic insulating layers may be removed in the area in which the slit SLT included in the connection portion 230 of the metal plate 200 and the display panel 100 overlap each other in the third direction DR3, thereby improving flexibility of the device 1 when the display device 1 is folded.

Hereinafter, other embodiments of the display device will be described. In following embodiments, the same reference numerals refer to the same components as those in the previously described embodiment. Duplicate descriptions thereof will be omitted or simplified, and rather, following description may be based on differences therebetween.

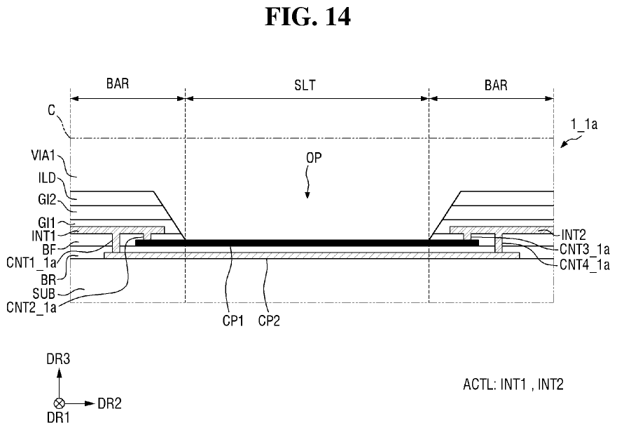

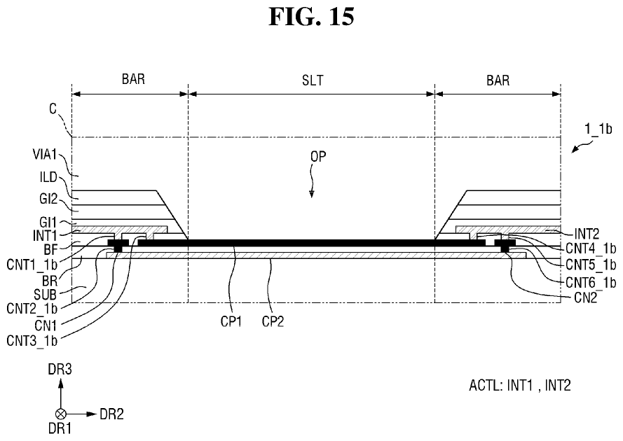

FIG. 14 is an enlarged view of the area C of FIG. 12 according to another embodiment. FIG. 15 to FIG. 21 are enlarged views of the area C of FIG. 12 according to still further embodiment.

Referring to FIG. 14, this embodiment is different from the embodiment according to FIG. 13 in that a plurality of connection lines CP are disposed in the second area in which the second pixel circuit PC2 is disposed and in which the bar BAR included in the connection portion 230 of the metal plate 200 and the display panel 100 overlap each other in the third direction DR3, the area where the slit SLT included in the connection portion 230 of the metal plate 200 and the display panel 100 overlap each other in the third direction DR3, and the first area where the first pixel PX1 and the first pixel circuit PC1 are disposed and in which the bar BAR included in the connection portion 230 of the metal plate 200 and the display panel 100 overlap each other in the third direction DR3, and the first portion INT1 and the second portion INT2 of the initialization line INT are electrically connected to each other via the plurality of connection lines CP.

Specifically, according to an embodiment according to FIG. 14, in the second area in which the second pixel circuit PC2 is disposed and in which the bar BAR included in the connection portion 230 of the metal plate 200 and the display panel 100 overlap each other in the third direction DR3, the area where the slit SLT included in the connection portion 230 of the metal plate 200 and the display panel 100 overlap each other in the third direction DR3, and the first area where the first pixel PX1 and the first pixel circuit PC1 are disposed and in which the bar BAR included in the connection portion 230 of the metal plate 200 and the display panel 100 overlap each other in the third direction DR3, the first connection line CP1 may be disposed on the barrier layer BR, and a second connection line CP2 may be disposed on the substrate SUB so as to overlap the first connection line CP in the third direction DR3.

In this embodiment, the second connection line CP2 may include the same material as that of the first connection line CP1. However, the disclosure is not limited thereto. In some embodiments, the second connection line CP2 may include a conductive material including a material different from that of the first connection line CP1.

Further, the first portion INT1 of the initialization line INT may be electrically connected to the second connection line CP2 via a first contact hole CNTI_1a extending through the buffer layer BF and the barrier layer BR and may be electrically connected to the first connection line CP1 via a second contact hole CNT2_1a extending through the buffer layer BF, so that the first portion INT1 of initialization line INT may be connected to both the first connection line CP1 and the second connection line CP2.

Further, the second portion INT2 of the initialization line INT may be electrically connected to the first connection line CP1 via a third contact hole CNT3_1a extending through the buffer layer BF, and may be electrically connected to the second connection line CP2 via a fourth contact hole CNT4_1a extending through the buffer layer BF and barrier layer BR, such that the second portion INT1 of the initialization line INT may be connected to both the first connection line CP1 and the second connection line CP2.

Therefore, in a display device 1_1a according to this embodiment, the first portion INT1 and the second portion INT2 of the initialization line INT may be connected to each other via both the first connection line CP1 and the second connection line CP2. Thus, even when one of the first connection line CP1 and the second connection line CP2 becomes discontinuous due to an external shock, the electrical connection between the first portion INT1 and the second portion INT2 of the initialization line INT may be maintained via the remaining connection line. This may effectively prevent discontinuity of the conductive line that may occur in the area in which the slit SLT included in the connection portion 230 of the metal plate 200 and the display panel 100 overlap each other in the third direction DR3.

Referring to FIG. 15, this embodiment is different from the embodiment according to FIG. 14 in which the first portion INT1 and the second portion INT2 of the initialization line INT are electrically connected to the second connection line CP2 respectively via the first contact hole CNT1_1a (see FIG. 14) and the fourth contact hole CNT4_1a (see FIG. 14) extending through the buffer layer BF. The first portion INT1 of the initialization line INT is electrically connected to a first connection-assisting electrode CN1 via a first contact hole CNT1_1b extending through the buffer layer BF, and the first connection-assisting electrode CN1 is electrically connected to the second connection line CP2 via a second contact hole CNT2_1b extending through the barrier layer BR.

A further difference is that the second portion INT1 of the initialization line INT is electrically connected to a second connection-assisting electrode CN2 via a fifth contact hole CNT5_1b extending through the buffer layer BF, and the second connection-assisting electrode CN2 is electrically connected to the second connection line CP2 via a sixth contact hole CNT6_1b extending through the barrier layer BR.

In this embodiment, each of the first connection-assisting electrode CN1 and the second connection-assisting electrode CN2 may include the same material as that of the first connection line CP1. However, the disclosure is not limited thereto, and in some embodiments, each of the first connection-assisting electrode CN1 and the second connection-assisting electrode CN2 may be made of a conductive material including a material different from that of the first connection line CP1.

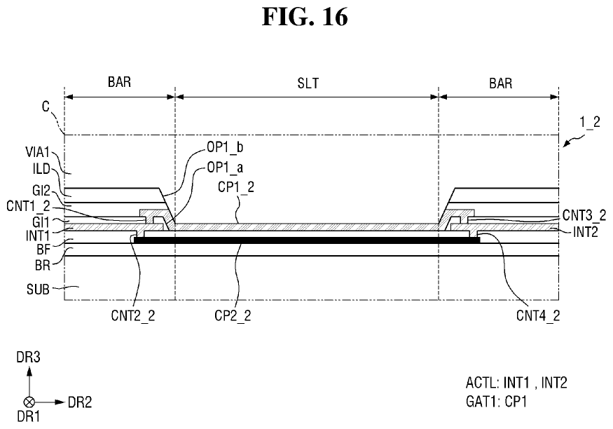

Referring to FIG. 16, this embodiment is different from the embodiment according to FIG. 14 in that the buffer layer BF is additionally disposed in the area where the slit SLT included in the connection portion 230 of the metal plate 200 and the display panel 100 overlap each other in the third direction DR3, and a first connection line CP1_2 is disposed in a different layer from a layer in which the buffer layer BF is disposed.

A further difference is that a first opening OP1_a and a second opening OP1_b are defined in a different manner from the opening OP shown in FIG. 14.

Specifically, in this embodiment, the buffer layer BF is additionally disposed so as to cover a second connection line CP2_2 in the area where the slit SLT included in the connection portion 230 of the metal plate 200 and the display panel 100 overlap each other in the third direction DR3. The first opening OP1_a may be defined by removing the first gate insulating layer GI1, and the second opening OP1_1b may be defined by removing the second gate insulating layer GI2 and the inter insulating layer ILD.

In this embodiment, the first connection line CP1_2 may be disposed on the first gate insulating layer GI1 in the second area where the second pixel circuit PC2 is disposed and in which the bar BAR included in the connection portion 230 of the metal plate 200 and the display panel 100 overlap each other in the third direction DR3, on the first opening OP1_a, and on the first gate insulating layer GI1 in the first area in which the bar BAR included in the connection portion 230 of the metal plate 200 and the display panel 100 overlap each other in the third direction DR3 and in which the first pixel PX1 and the first pixel circuit PC1 are disposed.

That is, the first connection line CP1_2 may extend along and be disposed on surfaces of the first gate insulating layer GI1 disposed in the first area, the first opening OP1_1a, and the first gate insulating layer GI1 disposed in the second area.

In this embodiment, the first connection line CP1_2 may include the same material as that of the first gate conductive layer GAT1 (see FIG. 11) disposed in the area where the display panel 100 overlaps the bar BAR included in the connection portion 230 of the metal plate 200 in the third direction DR3. However, the disclosure is not limited thereto, and in some embodiments, the first connection line CP1_2 may be made of a conductive material including a material different from that of the first gate conductive layer GAT1.

Referring to FIG. 16, a surface of the first connection line CP1_2 may be exposed through the second opening OP1_1b defined by removing the second gate insulating layer GI2 and inter insulating layer ILD. The first via insulating layer VIA1 may fill the second opening OP1_1b and may be in direct contact with the surface of the first connection line CP1_2 and a sidewall of the second opening OP1_1b.

The second connection line CP2_2 is substantially the same as the first connection line CP1 (see FIG. 14) as described above with reference to the embodiment according to FIG. 14. Thus, a description thereof will be omitted.

Therefore, the first portion INT1 of the initialization line INT may be connected to the first connection line CP1_2 and the second connection line CP2_2, respectively via a first contact hole CNT1_2 extending through the first gate insulating layer GI1 and a second contact hole CNT2_2 extending through the buffer layer BF. The second portion INT2 may be connected to the first connection line CP1_2 and the second connection line CP2_2, respectively via a third contact hole CNT3_2 extending through the first gate insulating layer GI1 and a fourth contact hole CNT4_2 extending through the buffer layer BF. Accordingly, the first portion INT1 of the initialization line INT and the second portion INT2 may be electrically connected to each other.

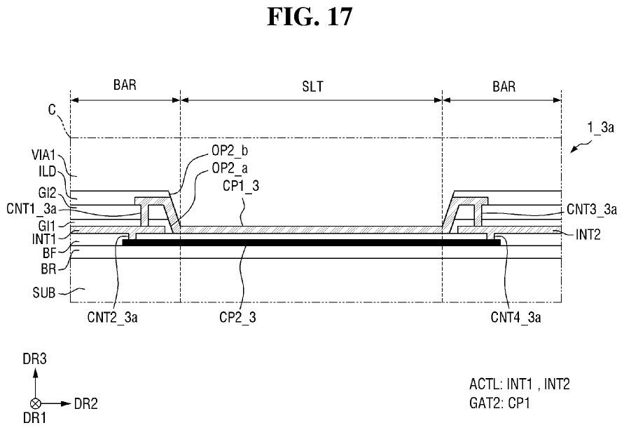

Referring to FIG. 17, the first connection line CP1_2 is disposed in a different layer from a layer of the first connection line CP1_2 (in FIG. 16) according to an embodiment according to FIG. 16. A first opening OP2_a and a second opening OP2_b are defined in a different manner from the first opening OP1_a and the second opening OP1_b shown in FIG. 16.

Specifically, in this embodiment, in the area where the slit SLT included in the connection portion 230 of the metal plate 200 and the display panel 100 overlap each other in the third direction DR3, the first gate insulating layer GI1 and the second gate insulating layer GI2 are removed to define the first opening OP2_a and the inter insulating layer ILD is removed to define the second opening OP2_b.

In this embodiment, the first connection line CP1_3 may be disposed on a portion of the second gate insulating layer GI2 positioned in the second area where the second pixel circuit PC2 is disposed and in which the bar BAR included in the connection portion 230 of the metal plate 200 and the display panel 100 overlap each other in the third direction DR3, on the first opening OP2, and on a portion of the second gate insulating layer GI2 positioned in the first area where the bar BAR included in the connection portion 230 of the metal plate 200 and the display panel 100 overlap each other in the third direction DR3 and in which the first pixel PX1 and the first pixel circuit PC1 are disposed.

That is, the first connection line CP1_3 may extend along and be disposed on surfaces of the portion of the second gate insulating layer GI2 disposed in the second area, the first opening OP2_a, and the portion of the second gate insulating layer GI2 disposed in the first area.

In this embodiment, the first connection line CP1_3 may include the same material as that of the second gate conductive layer GAT2 (see FIG. 11) disposed in the area where the display panel 100 overlaps the bar BAR included in the connection portion 230 of the metal plate 200 in the third direction DR3. However, the disclosure is not limited thereto, and in some embodiments, the first connection line CP1_3 may be made of a conductive material including a material different from a material of the second gate conductive layer GAT2.

The second connection line CP2_3 is substantially the same as the first connection line CP1 (in FIG. 14) as described with reference to the embodiment according to FIG. 14. Thus, a description thereof is omitted.

Therefore, the first portion INT1 of the initialization line INT may be connected to the first connection line CP1_3 and the second connection line CP2_3 respectively via a first contact hole CNT1_3a extending through the first gate insulating layer GI1 and the second gate insulating layer GI2 and a second contact hole CNT2_3a extending through the buffer layer BF. The second portion INT2 thereof may be connected to the first connection line CP1_3 and the second connection line CP2_3 respectively via a third contact hole CNT3_3a extending through the first gate insulating layer GI1 and the second gate insulating layer GI2 and a fourth contact hole CNT4_3a extending through the buffer layer BF. Accordingly, the first portion INT1 and the second portion INT2 of the initialization line INT may be connected to each other in a double manner.

Referring to FIG. 17, a surface of the first connection line CP1_3 may be exposed through a second opening OP_2b. The first via insulating layer VIA1 may fill the second opening OP2_2b and may be in direct contact with the surface of the first connection line CP1_3 and a sidewall of the second opening OP2_2b.

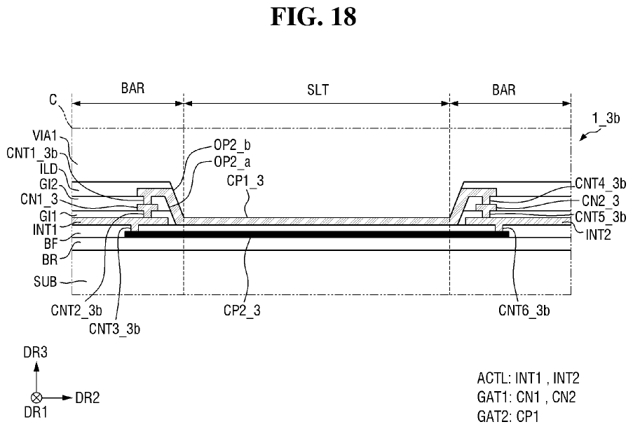

Referring to FIG. 18, this embodiment is different from the embodiment according to FIG. 17 in that a first connection line CP1_3 is electrically connected to a first connection-assisting electrode CN1_3 via a first contact hole CNT1_3b extending through the second gate insulating layer GI2, and the first connection-assisting electrode CN1_3 is electrically connected to the first portion INT1 of the initialization line INT via a second contact hole CNT2_3b extending through the first gate insulating layer GI1.

A further difference is that the first connection line CP1_3 is electrically connected to a second connection-assisting electrode CN2_3 via a fourth contact hole CNT4_3b extending through the second gate insulating layer GI2, and the second connection-assisting electrode CN2_3 is electrically connected to the second portion INT2 of the initialization line INT via the fifth contact hole CNT5_3b extending through the first gate insulating layer GI1.

In this embodiment, each of the first connection-assisting electrode CN1_3 and the second connection-assisting electrode CN2_3 may include the same material as that of the first gate conductive layer GAT1 (in FIG. 11) disposed in the area where the display panel 100 overlaps with the bar BAR included in the connection portion 230 of the metal plate 200 in the third direction DR3. However, the disclosure is not limited thereto, and in some embodiments, each of the first connection-assisting electrode CN1_3 and the second connection-assisting electrode CN2_3 may be made of a conductive material including a material different from that of the first gate conductive layer GAT1.

Therefore, the embodiments according to FIG. 15 to FIG. 18 may have the same effect as that of the display device 1_1a according to FIG. 14.

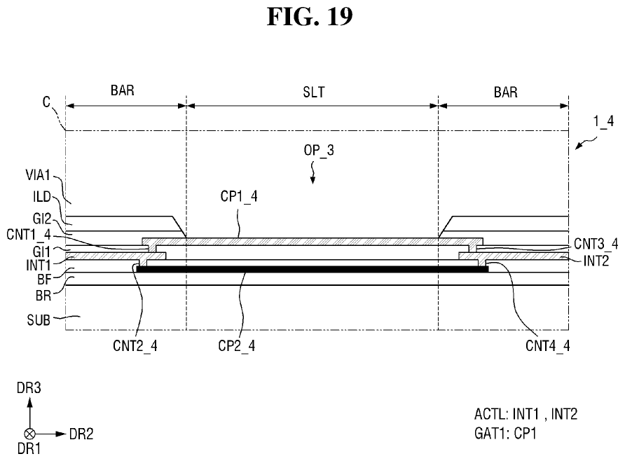

Referring to FIG. 19, this embodiment is different from the embodiment according to FIG. 16 in that the first gate insulating layer GI1 is additionally disposed in the area where the slit SLT included in the connection portion 230 of the metal plate 200 and the display panel 100 overlap each other in the third direction DR3, and one opening OP_3 is defined in a different manner from the first opening OP1_a and the second opening OP1_b as shown in FIG. 16.

Specifically, in this embodiment, the first gate insulating layer GI1 may be additionally disposed in the area where the slit SLT included in the connection portion 230 of the metal plate 200 and the display panel 100 overlap each other in the third direction DR3. The opening OP_3 may be defined by removing the second gate insulating layer GI2 and inter insulating layer ILD.

In this embodiment, a first connection line CP1_4 may be disposed on a portion of the first gate insulating layer GI1 in the second area where the second pixel circuit PC2 is disposed and where the bar BAR included in the connection portion 230 of the metal plate 200 and the display panel 100 overlap each other in the third direction DR3, on the opening OP3, and on a portion of the first gate insulating layer GI1 in the first area where the bar BAR included in the connection portion 230 of the metal plate 200 and the display panel 100 overlap each other in the third direction DR3 and in which the first pixel PX1 and the first pixel circuit PC1 are disposed.

That is, in the embodiment according to FIG. 16, the first connection line CP1_2 (see FIG. 16) is disposed on surfaces of a portion of the first gate insulating layer GI1 disposed in the first area, on the first opening OP1_a (see FIG. 16), and a portion of the first insulating layer GI1 (see FIG. 16), whereas in this embodiment, the first connection line CP1_4 is disposed on the first gate insulating layer GI1 in the areas in which the bar BAR and the slit SLT included in the connection portion 230 of the metal plate 200 and the display panel 100 overlap each other in the third direction DR3 and extends in the second direction DR2 and is free of a curved portion.

In this embodiment, a surface of the first connection line CP1_4 may be exposed through the opening OP_3. The first via insulating layer VIA1 may fill the opening OP_3 and directly contact the surface of the first connection line CP1_4 and a sidewall of opening OP_3.

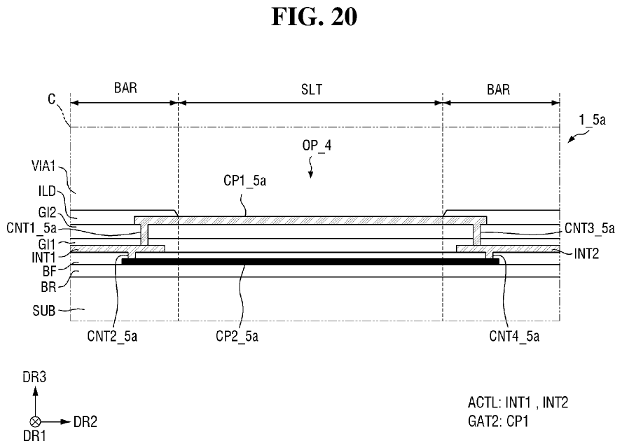

Referring to FIG. 20, this embodiment is different from the embodiment according to FIG. 17 in that the first gate insulating layer GI1 and the second gate insulating layer GI2 are additionally disposed in the area in which the slit SLT included in the connection portion 230 of the metal plate 200 and the display panel 100 overlap each other in the third direction DR3, and one opening OP_4 is defined in a different manner from the first opening OP2_a and the second opening OP2_b as shown in FIG. 17.

Specifically, in this embodiment, the first gate insulating layer GI1 and the second gate insulating layer GI2 are additionally disposed in the area where the slit SLT included in the connection portion 230 of the metal plate 200 and the display panel 100 overlap each other in the third direction DR3. The opening OP_4 is defined by removing the inter insulating layer ILD.

In this embodiment, a first connection line CP1_5a is disposed on a portion of the second gate insulating layer GI2 disposed in the second area where the bar BAR included in the connection portion 230 of the metal plate 200 and the display panel 100 overlap each other in the third direction DR3 and where the second pixel circuit PC2 is disposed, on the opening OP4, and on a portion of the second gate insulating layer GI2 disposed in the first area where the first pixel PX1 and the first pixel circuit PC1 are disposed and where the bar BAR included in the connection portion 230 of the metal plate 200 and the display panel 100 overlap each other in the third direction DR3.

That is, in the embodiment according to FIG. 17, the first connection line CP1_3 (see FIG. 17) is disposed on and extends along surfaces of the portion of the second gate insulating layer GI2 (see FIG. 17) in the first area, the first opening OP2_1a (see FIG. 17), and the portion of the second gate insulating layer GI2 disposed in the second area, whereas in this embodiment, the first connection line CP1_5a is disposed on the second gate insulating layer GI2 in the areas in which the bar BAR and the slit SLT included in the connection portion 230 of the metal plate 200 and the display panel 100 overlap each other in the third direction DR3 and extends in the second direction DR2 and is free of a curved portion.

In this embodiment, the surface of the first connection line CP1_5a may be exposed through the opening OP_4, and the first via insulating layer VIA1 may fill the opening OP_4 and may be in direct contact with the surface of the first connection line CP1_5a and a sidewall of opening OP_4.

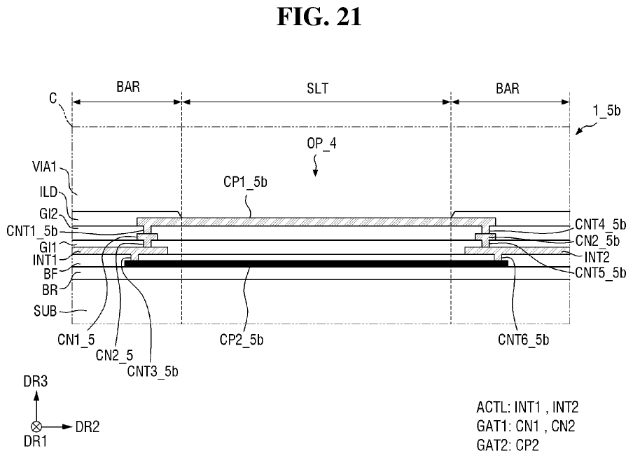

Referring to FIG. 21, this embodiment is different from the embodiment according to FIG. 18 in which the first gate insulating layer GI1 and the second gate insulating layer GI2 are additionally disposed in the area in which the slit SLT included in the connection portion 230 of the metal plate 200 and the display panel 100 overlaps each other in the third direction DR3, and one opening OP_4 is defined in a different manner from the first opening OP2_a and the second opening OP2_b as shown in FIG. 18.

In this embodiment, the first connection line CP1_5b is substantially the same as the first connection line CP1_5a (see FIG. 20) according to an embodiment of FIG. 20. Descriptions of a first connection-assisting electrode CN1_5b, a second connection-assisting electrode CN2_5b, and a plurality of contact holes CNT are substantially the same as those of the first connection-assisting electrode CN1_3 (see FIG. 18), the second connection-assisting electrode CN1_3 (see FIG. 18), and the plurality of contact holes CNT according to the embodiment of FIG. 18. Thus, descriptions thereof will be omitted.

According to the embodiments according to FIG. 18 to FIG. 21, the connection line CP is disposed on and extends along on the first gate insulating layer GI1 or the second gate insulating layer GI2 and is free of the curved portion, thereby effectively preventing discontinuity of the connection line CP due to an external impact to the display panel 100 or when the display device is bent.

In concluding the detailed description, those skilled in the art will appreciate that many variations and modifications can be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a substrate including a first non-bendable portion, a second non-bendable portion, and a bendable portion that is interposed between the first non-bendable portion and the second non-bendable portion;
a metal plate disposed on a rear face of the substrate, wherein the metal plate includes:
a first plate portion overlapping the first non-bendable portion,
a second plate portion overlapping the second non-bendable portion, and
a connection portion between the first plate portion and the second plate portion, the connection portion including a first bar and a second bar that are separated by a slit;
wherein the substrate includes:
a first area in which the first bar and the bendable portion overlap each other,
a second area in which the slit and the bendable portion overlap each other, and
a third area in which the second bar and the bendable portion overlap each other, wherein the second area is interposed between the first and third areas,
an initialization line including:
a first portion disposed on the first area, and
a second portion disposed on the third area and spaced apart from the first portion with the second area being disposed between the first portion and the third second portion,
a first pixel circuit disposed on the first area and connected to the first portion of the initialization line;
a second pixel circuit disposed on the third area and connected to the second portion of the initialization line; and
a first connection line connecting the first portion and the second portion to each other,
wherein the first connection line is disposed on the first area, the second area, and the third area, and
wherein the first connection line is disposed in a different layer from a layer in which the first portion and the second portion are disposed.

2. The device of claim 1, wherein the device further comprises:
a buffer layer disposed on the substrate;
a first gate insulating layer disposed on the buffer layer;
a second gate insulating layer disposed on the first gate insulating layer;
an inter insulating layer disposed on the second gate insulating layer; and
an opening defined in the second area above the first connection line.

3. The device of claim 2, wherein the device further comprises:
a lower metal layer disposed between the substrate and the buffer layer,
wherein the first connection line is disposed in the same layer as a layer in which the lower metal layer is disposed, and
wherein the first connection line is made of the same material as a material of the lower metal layer.

4. The device of claim 3, wherein the first pixel circuit includes:
a semiconductor layer disposed between the buffer layer and the first gate insulating layer,
a gate electrode disposed between the first gate insulating layer and the second gate insulating layer, and
a capacitor electrode disposed between the second gate insulating layer and the inter insulating layer,
wherein the first portion is disposed between a portion of the buffer layer and a portion of the first gate insulating layer disposed in the first area,
wherein the second portion is disposed between a portion of the buffer layer and a portion of the first gate insulating layer disposed in the third area, and
wherein the first portion and the second portion are made of the same material as a material of the semiconductor layer.

5. The device of claim 4, wherein the lower metal layer overlaps the semiconductor layer.

6. The device of claim 4, wherein the device further comprises a second connection line connecting the first portion and the second portion to each other, and
wherein the second connection line is disposed in the first area, the second area, and the third area, and
wherein the second connection line is disposed in a different layer from a layer of the first connection line.

7. The device of claim 6, wherein the second connection line overlaps the first connection line.

8. The device of claim 2, wherein the device further comprises a via insulating layer disposed in the first area, the second area, and the third area,
wherein a via insulating layer is disposed on the inter insulating layer,
wherein the via insulating layer fills the opening in the second area, and
wherein the via insulating layer directly contacts a portion of the first connection line through the opening.

9. The device of claim 8, wherein a thickness of a portion of the via insulating layer disposed in the second area is larger than a thickness of a portion of the via insulating layer disposed in each of the first area and the third area.

10. The device of claim 6, wherein the device further comprises the buffer layer covering a portion of the first connection line in the second area,
wherein the second connection line is in direct contact with the buffer layer.

11. The device of claim 6, wherein the second connection line is made of the same material as a material of the gate electrode.

12. The device of claim 6, wherein the second connection line is made of the same material as a material of the capacitor electrode.

13. The device of claim 1, wherein the device further comprises:
a first pixel circuit disposed on the third area;
a first light-emitting element disposed on the first area and connected to the first pixel circuit disposed on the first area;
a first light-emitting element disposed on the third area and connected to the first pixel circuit disposed on the third area; and
a second light-emitting element disposed on the second area and connected to the second pixel circuit disposed on the third area,
wherein the first light-emitting element does not overlap the first connection line, and
wherein the second light-emitting element overlaps the first connection line.

14. The device of claim 1, wherein neither of the first pixel circuit and the second pixel circuit overlap the second area.

15. A display device comprising:
a substrate including a first non-bendable portion, a second non-bendable portion, and a bendable portion that is disposed between the first non-bendable portion and the second non-bendable portion;
a metal plate disposed on a rear face of the substrate, wherein the metal plate includes:
a first plate portion overlapping the first non-bendable portion,
a second plate portion overlapping the second non-bendable portion, and
wherein the substrate includes:
a first area in which the first bar and the bendable portion overlap each other,
a second area in which the slit and the bendable portion overlap each other, and
a third area in which the second bar and the bendable portion overlap each other, wherein the second area is interposed between the first and third areas,
a first light-emitting element disposed on each of the first area and the third area;
a second light-emitting element disposed on the second area;
a first pixel circuit disposed on each of the first area and the third area; and
a second pixel circuit disposed on the third area,
wherein the first light-emitting element overlaps and is connected to the first pixel circuit in each of the first and third areas, and
wherein the second light-emitting element is in a mutually exclusive area with the first pixel circuit and the second pixel circuit and is connected to the second pixel circuit.

16. The device of claim 15, wherein the device further comprises:
a voltage line having:
a first portion disposed on the first area, and
a second portion disposed on the third area and spaced apart from the first portion while the second area is disposed therebetween, and a connection line connecting the first portion and the second portion to each other,
wherein the first portion is connected to the first pixel circuit on the first area,
wherein the second portion is connected to the second pixel circuit on the third area,
wherein the connection line is disposed on the first area, the second area, and the third area, and
wherein the connection line is disposed in a different layer from a layer of each of the first portion and the second portion.

17. The device of claim 16, wherein the device further comprises a connection electrode disposed on the first area and the second area, and connected to the second pixel circuit on the third area,
wherein the second light-emitting element is connected to a portion of the connection electrode on the second area.

18. The device of claim 17, wherein at least a portion of the connection line overlaps the connection electrode.

19. The device of claim 6, wherein the connection line and the first light-emitting element are on mutually exclusive parts of each of the first and third areas, and
wherein the connection line overlaps the second light-emitting element.

20. The device of claim 15, wherein neither of the first pixel circuit and the second pixel circuit overlaps the second area.
